(19) United States
(12) Patent Application Publication
(10) Pub. No.: US 2025/0149858 A1
(43) Pub. Date: May 8, 2025

(54) SURFACE EMITTING LASER, SURFACE EMITTING LASER ARRAY, AND MANUFACTURING METHOD FOR SURFACE EMITTING LASER

(71) Applicant: SONY GROUP CORPORATION, Tokyo (JP)

(72) Inventors: Masayuki TANAKA, Kanagawa (JP); Mikihiro YOKOZEKI, Kanagawa (JP)

(21) Appl. No.: 18/836,894

(22) PCT Filed: Jan. 20, 2023
(86) PCT No.: PCT/JP2023/001614

§ 371 Date: Aug. 8, 2024

(30) Foreign Application Priority Data
Mar. 8, 2022 (JP) 2022-035098

(51) Int. Cl. H01S 5/183; H01S 5/34

(52) U.S. Cl. CPC H01S 5/18308; H01S 5/18361; H01S 5/3416

(57) ABSTRACT

There is provided a surface emitting laser that can suppress position shift between the center of a current constriction region and the center of a lens-shaped part in plan view.

The surface emitting laser according to the present technology includes: first and second reflection mirrors; and a semiconductor structure that is disposed between the first and second reflection mirrors, and the semiconductor structure internally includes a convex-shaped part to which a current constriction region is set, and that protrudes toward a side of the second reflection mirror, and includes a lens-shaped part that meets the convex-shaped part on a top layer on the side of the second reflection mirror. According to the present technology, it is possible to provide the surface emitting laser that can suppress position shift between the center of the current constriction region and the center of the lens-shaped part in plan view.

### TECHNICAL FIELD

A technology according to the present disclosure (hereinafter, also referred to as a “present technology”) relates to a surface emitting laser, a surface emitting laser array, and a manufacturing method for the surface emitting laser.

### BACKGROUND ART

Conventionally, there is known a surface emitting laser that includes a current constriction region formed in a semiconductor structure disposed between first and second reflection mirrors (see, for example, PTL 1). This surface emitting laser includes a lens-shaped part that is an underlayer of the second reflection mirror (e.g., concave mirror) on the surface on a second reflection mirror side of the semiconductor structure.

### Citation List

### Patent Literature

[PTL 1]
WO 2018/083877

### SUMMARY

### Technical Problem

However, a conventional surface emitting laser has room for improvement regarding suppression of position shift between the center of the current constriction region and the center of the lens-shaped part in plan view.

It is therefore a main object of the present technology to provide a surface emitting laser that can suppress position shift between the center of a current constriction region and the center of a lens-shaped part in plan view.

### Solution to Problem

The present technology provides a surface emitting laser that includes: first and second reflection mirrors; and
a semiconductor structure that is disposed between the first and second reflection mirrors, and
the semiconductor structure internally includes a convex-shaped part to which a current constriction region is set, and that protrudes toward a side of the second reflection mirror, and includes a lens-shaped part that meets the convex-shaped part on a top layer on the side of the second reflection mirror.

The lens-shaped part may protrude toward the side of the second reflection mirror, and the second reflection mirror may be a concave mirror that is provided along the lens-shaped part.

The convex-shaped part may have a lens shape.

The convex-shaped part may have a mesa shape.

The convex-shaped part may include a tunnel junction layer.

The convex-shaped part may further include at least one layer that is laminated on the tunnel junction layer.

The at least one layer may include a cap layer that constitutes at least a top part of the convex-shaped part.

The cap layer may be made of the same material as a material of the top layer.

The at least one layer may include a spacer layer that constitutes at least a bottom part of the convex-shaped part.

The semiconductor structure may include a tunnel junction layer, and the convex-shaped part may be provided on a face of the tunnel junction layer on the side of second reflection mirror.

The semiconductor structure may include an active layer that is disposed on a side of the first reflection mirror of the convex-shaped part, a first semiconductor layer that is disposed between the convex-shaped part and the active layer, and a second semiconductor layer that buries surroundings of the convex-shaped part and includes the lens-shaped part.

A thickness of a portion of the first semiconductor layer that does not meet the convex-shaped part may be thinner than a thickness of a portion that meets the convex-shaped part.

The tunnel junction layer may include a p-type semiconductor region and an n-type semiconductor region that are mutually laminated, and at least one of the p-type semiconductor region and the n-type semiconductor region may be made of InP.

The tunnel junction layer may include a p-type semiconductor region and an n-type semiconductor region that are mutually laminated, and at least one of the p-type semiconductor region and the n-type semiconductor region may be made of AlGaInAs.

The first reflection mirror may be a semiconductor multilayer film reflection mirror or a dielectric multilayer film reflection mirror.

One of the first and second reflection mirrors may have a laminated structure in which a multilayer film reflection mirror and a metal reflection mirror are laminated.

The present technology also provides a surface emitting laser array formed by disposing in an array a plurality of the surface emitting lasers.

The present technology also provides a manufacturing method for a surface emitting laser that includes:
laminating a plurality of semiconductor layers on a substrate, and generating a laminated body;
forming a resist of a lens shape on the laminated body;
etching the laminated body using the resist as a mask, and forming a convex-shaped part of a lens shape;
laminating a buried layer on the laminated body in which the convex-shaped part has been formed, and forming in the buried layer a lens-shaped part that meets the convex-shaped part; and
forming a reflection mirror on the lens-shaped part.

The present technology also provides a manufacturing method for a surface emitting laser that includes:
laminating a plurality of semiconductor layers on a substrate, and generating a laminated body;
forming a resist of a convex shape on the laminated body;
etching the laminated body using the resist as a mask, and forming a first convex-shaped part;
laminating a buried layer on the laminated body in which the first convex-shaped part has been formed, and forming in the buried layer a second convex-shaped part that meets the first convex-shaped part;
etching the second convex-shaped part, and forming a lens-shaped part; and
forming a reflection mirror on the lens-shaped part.

### BRIEF DESCRIPTION OF DRAWINGS

FIG. 1 is a cross-sectional view of a surface emitting laser according to example 1 of an embodiment of the present technology.

FIGS. 2A and 2B are views for describing a relationship between a resonator length and a curvature radius of a lens-shaped part.

FIGS. 3A and 3B are views for describing a relationship between an aperture diameter and the curvature radius of the lens-shaped part.

FIG. 4 is a flowchart for describing an example of a manufacturing method for the surface emitting laser in FIG. 1.

FIGS. 5A and 5B are cross-sectional views of each process of the example of the manufacturing method for the surface emitting laser in FIG. 1.

FIGS. 6A and 6B are cross-sectional views of each process of the example of the manufacturing method for the surface emitting laser in FIG. 1.

FIGS. 7A and 7B are cross-sectional views of each process of the example of the manufacturing method for the surface emitting laser in FIG. 1.

FIGS. 8A and 8B are cross-sectional views of each process of the example of the manufacturing method for the surface emitting laser in FIG. 1.

FIGS. 9A and 9B are cross-sectional views of each process of the example of the manufacturing method for the surface emitting laser in FIG. 1.

FIG. 10 is a cross-sectional view of the surface emitting laser according to example 2 of the embodiment of the present technology.

FIG. 11 is a cross-sectional view of the surface emitting laser according to example 3 of the embodiment of the present technology.

FIG. 12 is a cross-sectional view of the surface emitting laser according to example 4 of the embodiment of the present technology.

FIG. 13 is a cross-sectional view of the surface emitting laser according to example 5 of the embodiment of the present technology.

FIG. 14 is a flowchart for describing an example of the manufacturing method for the surface emitting laser in FIG. 13.

FIGS. 15A and 15B are cross-sectional views of each process of the example of the manufacturing method for the surface emitting laser in FIG. 13.

FIGS. 16A and 16B are cross-sectional views of each process of the example of the manufacturing method for the surface emitting laser in FIG. 13.

FIGS. 17A and 17B are cross-sectional views of each process of the example of the manufacturing method for the surface emitting laser in FIG. 13.

FIGS. 18A and 18B are cross-sectional views of each process of the example of the manufacturing method for the surface emitting laser in FIG. 13.

FIGS. 19A and 19B are cross-sectional views of each process of the example of the manufacturing method for the surface emitting laser in FIG. 13.

FIG. 20 is a cross-sectional view of the surface emitting laser according to example 6 of the embodiment of the present technology.

FIG. 21 is a flowchart for describing the example of the manufacturing method for the surface emitting laser in FIG. 20.

FIGS. 22A and 22B are cross-sectional views of each process of the example of the manufacturing method for the surface emitting laser in FIG. 20.

FIGS. 23A and 23B are cross-sectional views of each process of the example of the manufacturing method for the surface emitting laser in FIG. 20.

FIGS. 25A and 24B are cross-sectional views of each process of the example of the manufacturing method for the surface emitting laser in FIG. 20.

FIGS. 25A and 25B are cross-sectional views of each process of the example of the manufacturing method for the surface emitting laser in FIG. 20.

FIGS. 26A and 26B are cross-sectional views of each process of the example of the manufacturing method for the surface emitting laser in FIG. 20.

FIG. 27 is a cross-sectional view of the surface emitting laser according to example 7 of the embodiment of the present technology.

FIG. 28 is a cross-sectional view of the surface emitting laser according to example 8 of the embodiment of the present technology.

FIG. 29 is a cross-sectional view of the surface emitting laser according to example 9 of the embodiment of the present technology.

FIG. 30 is a cross-sectional view of the surface emitting laser according to example 10 of the embodiment of the present technology.

FIG. 31 is a cross-sectional view of the surface emitting laser according to example 11 of the embodiment of the present technology.

FIG. 32 is a cross-sectional view of the surface emitting laser according to example 12 of the embodiment of the present technology.

FIG. 33 is a cross-sectional view of the surface emitting laser according to example 13 of the embodiment of the present technology.

FIG. 34 is a cross-sectional view of the surface emitting laser according to example 14 of the embodiment of the present technology.

FIG. 35 is a cross-sectional view of the surface emitting laser according to example 15 of the embodiment of the present technology.

FIG. 36 is a cross-sectional view of a surface emitting laser array according to example 16 of the embodiment of the present technology.

FIG. 37 is a diagram illustrating an example of application of the surface emitting laser according to the present technology to a distance measurement device.

FIG. 38 is a block diagram illustrating an example of a schematic configuration of a vehicle control system.

FIG. 39 is an explanatory view illustrating an example of an installation position of the distance measurement device.

### DESCRIPTION OF EMBODIMENTS

A preferred embodiment of the present technology will be described in detail with reference to the accompanying figures below. In the present specification and the drawings, components having substantially the same functional configuration will be denoted by the same reference numerals, and thus repeated descriptions thereof will be omitted. The embodiments to be described below describe a representative embodiment of the present technology, and the scope of the present technology should not be narrowly interpreted based on this. Even when the present specification describes that a surface emitting laser, a surface emitting laser array, and a manufacturing method for the surface emitting laser according to the present technology have a plurality of effects, the surface emitting laser, the surface emitting laser array, and the manufacturing method for the surface emitting laser according to the present technology may have at least one effect. The effects described in the present specification are merely exemplary and are not limited, and other advantageous effects may be obtained.

In addition, the description will be made in the following order.
0. Introduction
1. Surface Emitting Laser According to Example 1 of Embodiment of Present Technology
2. Surface Emitting Laser According to Example 2 of Embodiment of Present Technology
3. Surface Emitting Laser According to Example 3 of Embodiment of Present Technology
4. Surface Emitting Laser According to Example 4 of Embodiment of Present Technology
5. Surface Emitting Laser According to Example 5 of Embodiment of Present Technology
6. Surface Emitting Laser According to Example 6 of Embodiment of Present Technology
7. Surface Emitting Laser According to Example 7 of Embodiment of Present Technology
8. Surface Emitting Laser According to Example 8 of Embodiment of Present Technology
9. Surface Emitting Laser According to Example 9 of Embodiment of Present Technology
10. Surface Emitting Laser According to Example 10 of Embodiment of Present Technology
11. Surface Emitting Laser According to Example 11 of Embodiment of Present Technology
12. Surface Emitting Laser According to Example 12 of Embodiment of Present Technology
13. Surface Emitting Laser According to Example 13 of Embodiment of Present Technology
14. Surface Emitting Laser According to Example 14 of Embodiment of Present Technology
15. Surface Emitting Laser According to Example 15 of Embodiment of Present Technology
16. Surface Emitting Laser Array According to Example 16 of Embodiment of Present Technology
17. Modification Example of Present Technology
18. Example of Application to Electronic Device
19. Application of Surface Emitting Laser to Distance Measurement Device
20. Example Where Distance Measurement Device is Mounted on Moving Body

### 0. Introduction

By the way, it is studied that an eye-safe surface emitting laser (VCSEL) of a long wavelength range achieves a high output. Currently, although a VCSEL of a short resonator that uses a Buried Tunnel Junction (BTJ) has been developed as a surface emitting laser of a long wavelength range, it is indispensable to increase the length of a resonator to achieve a high output. However, increasing the resonator increases diffraction loss, and therefore it is possible to prevent this diffraction loss by adopting a concave mirror as a reflection mirror. For a VCSEL including a concave mirror as a reflection mirror, a current constriction region and a lens-shaped part that is an underlayer of the concave mirror are separately made, and therefore warp of a wafer, position adjustment accuracy, and the like make it very difficult to match the center of the current constriction region and the center of the concave mirror on a wafer plane. This shift of the centers causes diffraction loss.

Hence, as a result of earnest study, the inventors have developed a surface emitting laser according to the present technology as a surface emitting laser that can suppress position shift between the center of a current constriction region and the center of a lens-shaped part in plan view.

Hereinafter, some examples of the surface emitting laser according to the embodiment of the present technology will be described in detail.

### <1. Surface Emitting Laser According to Example 1 of Embodiment of Present Technology>

Hereinafter, a surface emitting laser 10-1 according to example 1 of the embodiment of the present technique will be described.

### <<Configuration of Surface Emitting Laser>>

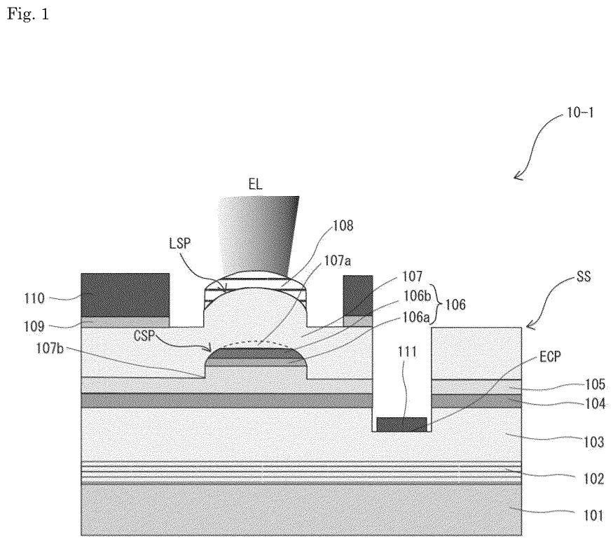

FIG. 1 is a cross-sectional view of a surface emitting laser 10-1 according to example 1 of the embodiment of the present technology. Hereinafter, description will be made assuming for convenience of description that an upper direction in the cross-sectional views in FIG. 1 and the other figures is an upper side, and a lower direction is a lower side.

### (Overall Configuration)

The surface emitting laser 10-1 is a Vertical Cavity Surface Emitting Laser (VCSEL). The surface emitting laser 10-1 is, for example, a VCSEL of a long wavelength range whose oscillation wavelength λ is, for example, 900 nm or more and, moreover, 1.4 μm or more. The oscillation wavelength λ is particularly preferably 1.2 μm or more and 2 μm or less. The surface emitting laser 10-1 is driven by, for example, a laser driver.

As illustrated in, for example, FIG. 1, the surface emitting laser 10-1 includes first and second reflection mirrors 102 and 108 that are mutually laminated, and a semiconductor structure SS that is disposed between the first and second reflection mirrors 102 and 108. For example, the second reflection mirror 108 is an emission side reflection mirror. The first reflection mirror 102 is also referred to as a lower reflection mirror. The second reflection mirror 108 is also referred to as an upper reflection mirror. The surface emitting laser 10-1 further includes a substrate 101 disposed on an opposite side to a semiconductor structure SS side of the first reflection mirror 102.

The semiconductor structure SS internally includes a convex-shaped part CSP to which a current constriction region is set, and that protrudes toward a second reflection mirror 108 side, and includes a lens-shaped part LSP that meets the convex-shaped part CSP on a top layer on the second reflection mirror 108 side. The convex-shaped part CSP has, for example, a lens shape that protrudes toward the second reflection mirror 108 side. The lens-shaped part LSP has, for example, a lens shape that is similar (e.g., identical) to that of the convex-shaped part CSP and protrudes toward the second reflection mirror 108 side. The surface of the lens-shaped part LSP is, for example, a curved surface such as a spherical surface or a paraboloidal surface.

The semiconductor structure SS further includes, for example, an active layer 104 that is disposed on a first reflection mirror 102 side of the convex-shaped part CSP, a first semiconductor layer 105 that is disposed between the convex-shaped part CSP and the active layer 104, and a second semiconductor layer 107 that buries surroundings of the convex-shaped part CSP and includes the lens-shaped part LSP. The semiconductor structure SS further includes a third semiconductor layer 103 that is disposed between the first reflection mirror 102 and the active layer 104.

The convex-shaped part CSP includes a tunnel junction layer 106. A region around the tunnel junction layer 106 of the second semiconductor layer 107 is a current constriction region. The convex-shaped part CSP includes a cap layer 107a that is laminated on the tunnel junction layer 106. The cap layer 107a constitutes at least the top part of the convex-shaped part CSP. The cap layer 107a is made of, for example, the same material as that of the top layer (second semiconductor layer 107) on the second reflection mirror 108 side of the semiconductor structure SS. The thickness of a portion of the first semiconductor layer 105 that does not meet the convex-shaped part CSP is thinner than the thickness of a portion that meets the convex-shaped part CSP.

A contact layer 109 of a circular shape is disposed on the surface on the second reflection mirror 108 side of the second semiconductor layer 107 so as to surround the lens-shaped part LSP. An anode electrode 110 of a circular shape is disposed on the contact layer 109 so as to surround the lens-shaped part LSP.

The semiconductor structure SS is provided with a recess part that is an electrode contact part ECP and has the bottom surface in the third semiconductor layer 103. A cathode electrode 111 is disposed on the bottom surface of the recess part that is the electrode contact part ECP.

### (Substrate)

The substrate 101 is, for example, an InP substrate.

### (First Reflection Mirror)

The first reflection mirror 102 is, for example, a semiconductor multilayer film reflection mirror (semiconductor DBR). The semiconductor multilayer film reflection mirror has a structure that a plurality of types (e.g., two types) of refractive index layers (semiconductor layers) of respectively different refractive indices have optical thicknesses that are ¼ (λ/4) of the oscillation wavelength A and are mutually laminated. The first reflection mirror 102 is a compound semiconductor that lattice-matches with InP. A lattice constant of the first reflection mirror 102 is preferably within a range of ±0.2% of a lattice constant of InP. More specifically, the first reflection mirror 102 preferably contains AlGaInAs. More specifically, a pair of a refractive index layer of the first reflection mirror 102 is preferably InP/AlGaInAs or AlInAs/AlGaInAs.

### (Third Semiconductor Layer)

The third semiconductor layer 103 is, for example, an n-InP layer. As a dopant of the n-InP layer, for example, Si can be used. The third semiconductor layer is also referred to as a clad layer.

### (Active Layer)

The active layer 104 is made of, for example, a GaAs-based compound semiconductor or a GaAsP-based compound semiconductor. More specifically, the active layer 104 has, for example, a Multiple Quantum Well structure (MQW structure) that is made of AlGaInAs or GaInAsP. Here, the active layer 104 includes, for example, an AlGaInAs/AlGaInAs multiple quantum well layer. Although the composition and the film thickness of the AlGaInAs/AlGaInAs multiple quantum well layer are designed such that the oscillation wavelength is, for example, 1450 nm, it is preferable to introduce opposite strains in a well layer and a barrier layer. In this case, the magnitude of the strain is approximately 0.5 to 1.5%, and the number of wells is 2 to 86. A region of the active layer 104 meeting the tunnel junction layer 106 is a light emission region (current injection region). The light emission region of the active layer 104 is also a heat generation unit.

### (First Semiconductor Layer)

The first semiconductor layer 105 is, for example, a p-InP layer. As a dopant of the p-InP layer, for example, Mg can be used.

### (Tunnel Junction Layer and Second Semiconductor Layer)

The tunnel junction layer 106 and the second semiconductor layer 107 (buried layer) constitute a Buried Tunnel Junction (BTJ). The second semiconductor layer 107 is, for example, an n-InP layer. As a dopant of the n-InP layer, for example, Si can be used. The tunnel junction layer 106 has remarkably low resistance (very high carrier conductivity) compared to the surrounding second semiconductor layer 107, and is a current passing region. A region of the second semiconductor layer 107 surrounding the tunnel junction layer 106 functions as the current constriction region. The region of the second semiconductor layer 107 surrounding the tunnel junction layer 106 has a low refractive index than that of the tunnel junction layer 106, and also functions as a light constriction region (light trapping region). That is, the BTJ has both of a current constriction function and a light constriction function. The tunnel junction layer 106 is also a heat generation unit. The diameter of the tunnel junction layer 106 is, for example, approximately several μm to several tens of μm.

The BTJ is disposed on the second reflection mirror 108 side of the active layer 104. That is, the BTJ is located on an upstream side of a current path that goes from the anode electrode 110 to the cathode electrode 111 with respect to the active layer 104.

The tunnel junction layer 106 includes a p-type semiconductor region 106a and an n-type semiconductor region 106b that are laminated. Here, the p-type semiconductor region 106a is disposed on an active layer 104 side (lower side) of the n-type semiconductor region 106b. At least one of the p-type semiconductor region 106a and the n-type semiconductor region 106b may be made of InP. At least one of the p-type semiconductor region 106a and the n-type semiconductor region 106b may be made of AlGaInAs. For example, the p-type semiconductor region 106a is made of p-AlGaInAs that is doped with, for example, C, Mg, or Zn of a high concentration (e.g., 5×10¹⁹ [cm⁻³]). The n-type semiconductor region 106b is made of n-InP that is doped with, for example, Si or Te of a high concentration (e.g., 5×10¹⁹ [cm⁻³]). The film thickness (total film thickness) of the tunnel junction layer 106 is, for example, approximately several tens of nm. Here, the film thickness of each of the p-type semiconductor region 106a and the n-type semiconductor region 106b is, for example, 10 to 30 nm. Note that the p-type semiconductor region 106a may be made of heavily doped p-InP, and the n-type semiconductor region 106b may be made of heavily doped n-AlGaInAs.

### (Second Reflection Mirror)

The second reflection mirror 108 is, for example, a concave mirror that is provided along the lens-shaped part LSP. For example, the second reflection mirror 108 is a dielectric multilayer film reflection mirror (dielectric DBR). The dielectric multilayer film reflection mirror has a structure that a plurality of types (e.g., two types) of refractive index layers (dielectric layers) of respectively different refractive indices have optical thicknesses that are ¼ (λ/4) of the oscillation wavelength λ and are mutually laminated. The dielectric multilayer film reflection mirror that is the second reflection mirror 108 has the reflectance that is set slightly lower than that of the first reflection mirror 102. The second reflection mirror 108 is preferably made of a material containing at least one type of, for example, SiO₂, TiO₂, Ta₂O₅, SiN, amorphous Si, MgF₂, and CaF₂. For example, the dielectric multilayer film reflection mirror that is the second reflection mirror 108 has a structure formed by alternately laminating a high refractive index layers (e.g., Ta₂O₅ layer) and a low refractive index layer (e.g., SiO₂ layer).

### (Contact Layer)

The contact layer 109 is, for example, an n-InGaAs layer of a circular shape (e.g., ring shape). As a dopant of the n-InGaAs, for example, Si can be used.

### (Anode Electrode)

The anode electrode 110 includes a portion of a circular shape (e.g., ring shape) that is in contact with the contact layer 109. The anode electrode 110 is made of, for example, Au/Ni/AuGe, Au/Pt/Ti, or the like. The anode wiring 110 is electrically connected to, for example, an anode (positive electrode) of the laser driver.

### (Cathode Electrode)

The cathode electrode 111 is made of, for example, Au/Ni/AuGe, Au/Pt/Ti, or the like. The cathode electrode 111 is electrically connected to, for example, a cathode (negative electrode) of the laser driver.

### (Relationship Between Resonator Length and Curvature Radius of Lens-Shaped Part)

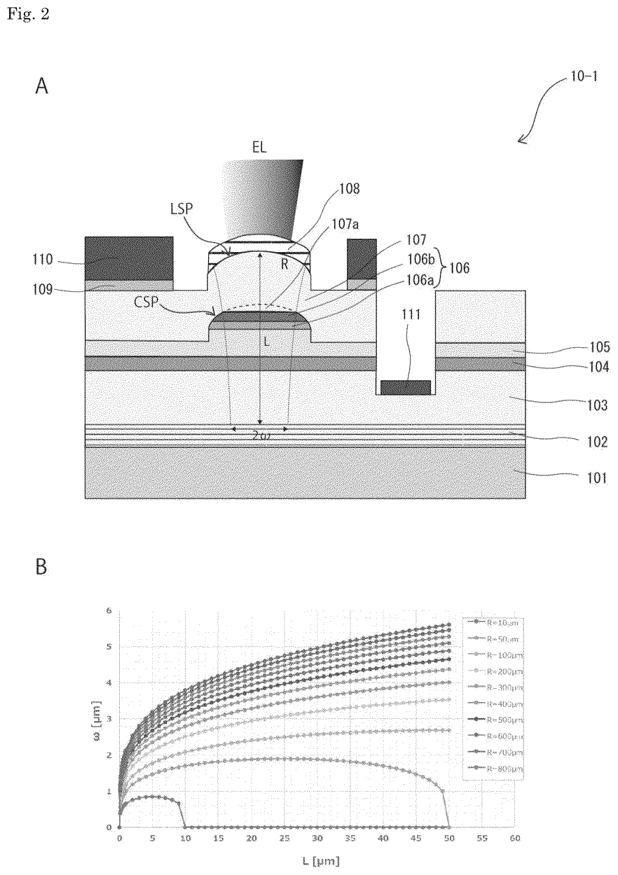

It is known that following Equation (1) holds for a curvature radius R of the lens-shaped part LSP, a resonator length L of the surface emitting laser 10-1, and a beam waist diameter 2ω illustrated in FIG. 2A.

$$[ Math . 1 ]$$

$$2 {ω}_{flat} = 2 \sqrt{\frac{λ}{n π} \sqrt{LR - {L}^{2}}} \qquad ( 1 )$$

Although design (L=R in above Equation (1)) that minimizes the beam waist diameter 2ω is an ideal state, when L>R holds due to a variation of a process or the like, diffraction loss occurs. Hence, such design is basically made that L<R holds. In this regard, since an oscillation threshold (threshold current) also becomes larger as the beam waist becomes larger, the design is made taking a balance into account. How the relationship between the resonator length L and the beam waist radius w) changes due to the curvature radius R when the wavelength λ in above Equation (1) is 1.45 μm, and a refractive index n is 3.2 is shown in a graph in FIG. 2B. As the curvature radius R is smaller (as the curvature is larger), the beam waist radius @ becomes smaller. It is found from FIG. 2B that, when, for example, the resonator length L is 50 μm, the curvature radius R at which the beam waist can be stably obtained is approximately 100 μm. Note that R in the first to tenth graphs from the bottom in FIG. 2B is 10 μm, 50 μm, 100 μm, 200 μm, 300 μm, 400 μm, 500 μm, 600 μm, 700 μm, and 800 μm.

### (Relationship Between Aperture Diameter and Curvature Radius of Lens-Shaped Part)

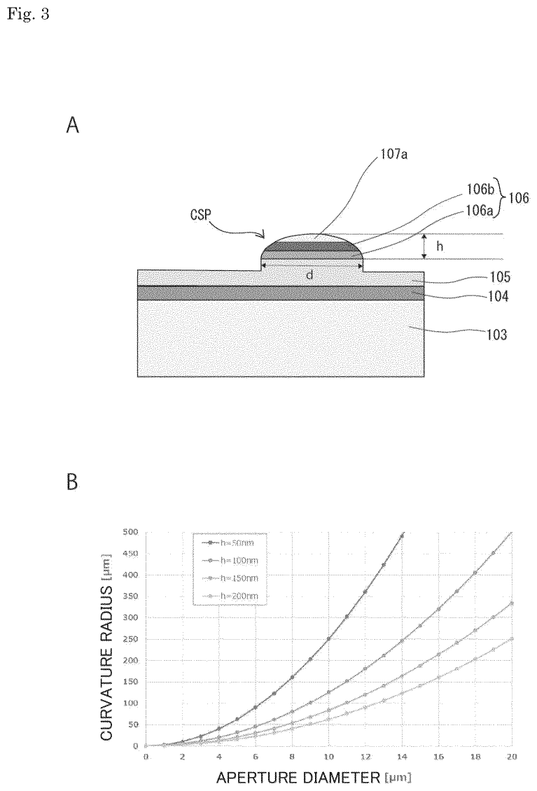

How a relationship between an aperture diameter d (the current constriction diameter of the BTJ) and the curvature radius R of the lens-shaped part LSP illustrated in FIG. 3A changes due to a height h of the convex-shaped part CSP is shown in FIG. 3B. The aperture diameter d is the diameter (more specifically, maximum diameter) of the tunnel junction layer 106 that determines the current injection region (light emission region), and is a basic parameter that is very important for design of the surface emitting laser 10-1 and determines oscillation characteristics. Furthermore, although the height of the convex-shaped part CSP is substantially determined based on the heights of the tunnel junction layer 106 and the cap layer 107a (n-InP layer), since a tunnel junction layer having an optimal film thickness for tunneling of carriers is generally designed, it is desirable to adjust the height of the convex-shaped part CSP in this case by adjusting the height of the cap layer 107a (n-InP layer). A result of obtaining the necessary height of the convex-shaped part CSP obtained from the relationship between the aperture diameter d and the curvature radius R is shown in FIG. 3B. In a case where, for example, the surface emitting laser 10-1 is made assuming that the curvature radius is 100 μm, the necessary lens height is approximately 50 nm when the aperture diameter is 6 μm, and is approximately 100 nm when the aperture diameter is 9 μm, is approximately 150 nm when the aperture diameter is 11 μm, and is approximately 200 nm when the aperture diameter is 13 μm likewise, and, taking these relationships into account, it is possible to arbitrarily set the curvature radius R and the height of the convex-shaped part CSP by determining the resonator length L and the aperture diameter d as design values of the surface emitting laser 10-1.

### <<Operation of Surface Emitting Laser>>

The current having flowed in the surface emitting laser 10-1 from the anode side of a laser driver via the anode electrode 110 is constricted by the BTJ, and is injected into the active layer 104 via the first semiconductor layer 105. In this case, the active layer 104 emits light, and this light reciprocates between the first and second reflection mirrors 102 and 108 while being constricted by the BTJ and amplified by the active layer 104, and is emitted as emission light EL (laser light) from the second reflection mirror 108 when the oscillation condition is satisfied. The current injected into the active layer 104 flows out toward the cathode side of the laser driver via the third semiconductor layer 103 and the cathode electrode 111 in this order.

### <<Manufacturing Method for Surface Emitting Laser>>

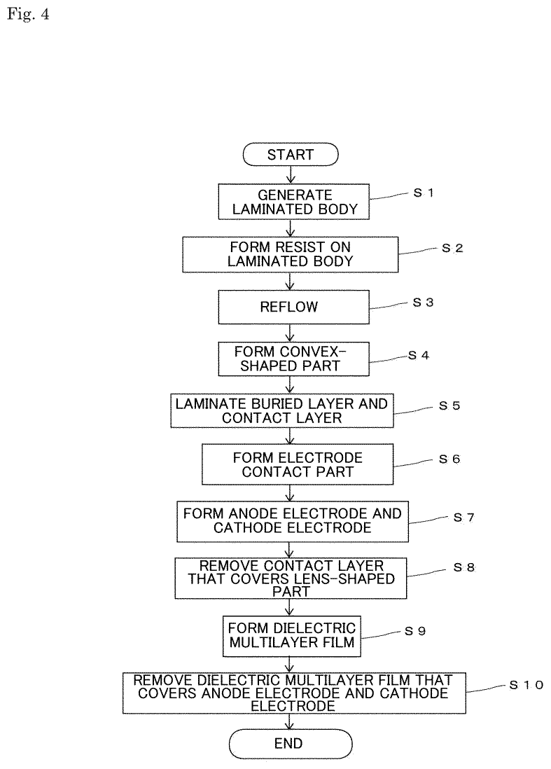

Hereinafter, the manufacturing method for the surface emitting laser 10-1 will be described with reference to the flowchart in FIG. 4 or the like. Here, for example, a semiconductor manufacturing method that uses a semiconductor manufacturing device simultaneously generates a plurality of the surface emitting lasers 10-1 on one wafer that is a base material of the substrate 101. Next, a series of the plurality of integrated surface emitting lasers 10-1 are separated to obtain the plurality of chip-shaped surface emitting lasers 10-1 (surface emitting laser chips).

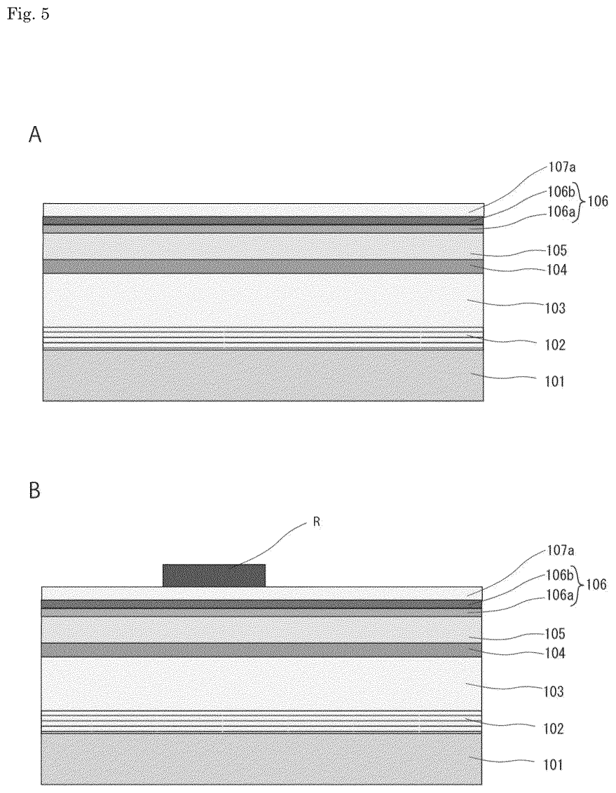

In first step S1, a laminated body is generated (see FIG. 5A). More specifically, the first reflection mirror 102, the third semiconductor layer 103, the active layer 104, the first semiconductor layer 105, the tunnel junction layer 106, and the cap layer 107a are grown in this order on the substrate 101 (e.g., InP substrate) by, for example, a Metal Organic Chemical Vapor Deposition method (MOCVD method).

In next step S2, a resist R is formed on the laminated body (see FIG. 5B). More specifically, first, the resist is applied to the entire surface of the laminated body. Next, the resist is exposed to light with a mask interposed therebetween to form the resist R (resist pattern) that covers only a portion at which the convex-shaped part CSP of the laminated body is to be formed.

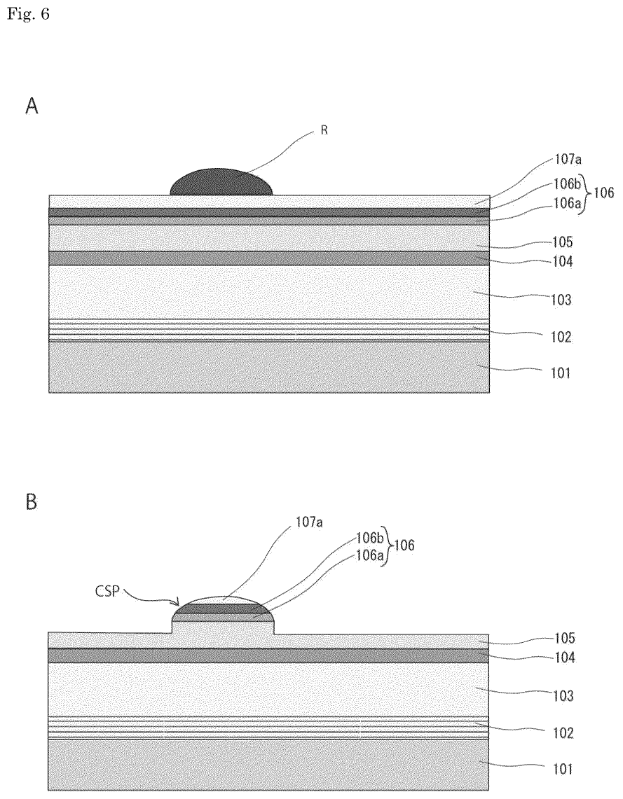

In next step S3, reflow (heating treatment) is performed (see FIG. 6A). More specifically, reflow is performed at, for example, 200° C. in temperature to hold up the resist R.

In next step S4, the convex-shaped part CSP is formed (see FIG. 6B). More specifically, by performing dry etching using the resist R as the mask, the shape of the resist R is transferred to the laminated body to form the convex-shaped part CSP. At this time, a region that does not meet to the convex-shaped part CSP of the first semiconductor layer 105 is partially etched by over etching, and a bump is formed in the first semiconductor layer 105. The height of this bump depends on the degree of over etching. In a case where etching controllability is high, it is also possible to eliminate the bump.

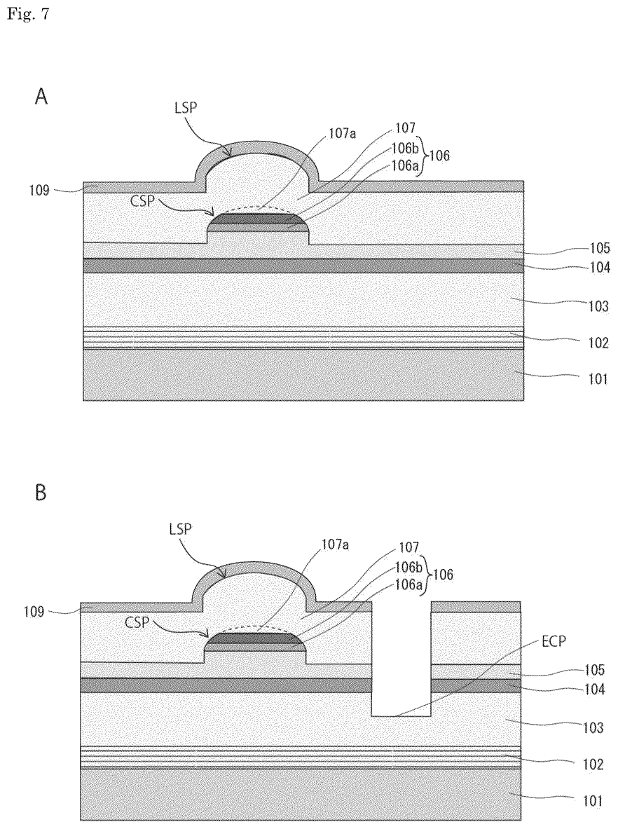

In next step S5, the second semiconductor layer 107 and the contact layer 109 that are buried layers are laminated (see FIG. 7A). More specifically, the second semiconductor layer 107 and the contact layer 109 that are buried layers are regrown in this order on the laminated body on which the convex-shaped part CSP has been formed, by, for example, the Metal Organic Chemical Vapor Deposition method (MOCVD method) to form the BTJ. As a result, the lens-shaped part LSP that meets the convex-shaped part CSP (the lens-shaped part LSP that goes along the convex-shaped part CSP) is formed in the second semiconductor layer 107.

In next step S6, the electrode contact part ECP is formed (see FIG. 7B). More specifically, the laminated body in which the second semiconductor layer 107 and the contact layer 109 have been formed is etched to form the electrode contact part ECP.

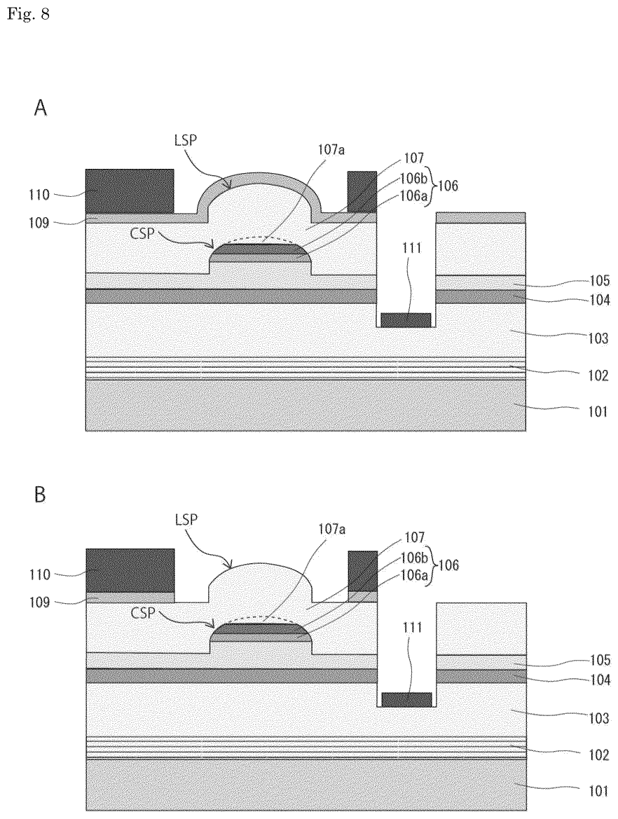

In next step S7, the anode electrode 110 and the cathode electrode 111 are formed (see FIG. 8A). More specifically, the anode electrode 110 of the circular shape is formed by, for example, a lift-off method so as to surround the lens-shaped part LSP on the laminated body, and the cathode electrode 111 is formed at the electrode contact part ECP.

In next step S8, the contact layer 109 that covers the lens-shaped part LSP is removed (see FIG. 8B). More specifically, a resist pattern that is opened on the portion that covers at least the lens-shaped part LSP of the contact layer 109 is formed on the laminated body, and the laminated body is etched using the resist pattern as the mask to remove the contact layer 109 that covers the lens-shaped part LSP and exposes the lens-shaped part LSP.

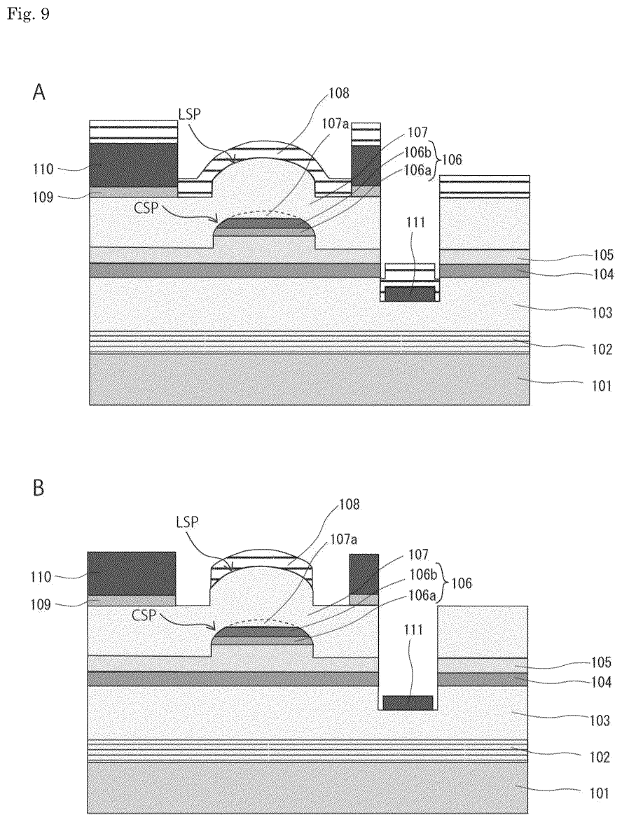

In next step S9, a dielectric multilayer film is formed (see FIG. 9A). More specifically, the dielectric multilayer film that is the material of the second reflection mirror 108 is formed on the entire surface of the laminated body from which the lens-shaped part LSP has been exposed.

In last step S10, the dielectric multilayer film that covers the anode electrode 110 and the cathode electrode 111 is removed (see FIG. 9B). More specifically, a resist pattern that covers the dielectric multilayer film on the lens-shaped part LSP is formed on the laminated body, and the dielectric multilayer film is etched using the resist pattern as the mask. As a result, only the dielectric multilayer film on the lens-shaped part LSP remains as the second reflection mirror 108.

### <<Effect of Surface Emitting Laser and Manufacturing Method for Surface Emitting Laser>>

The surface emitting laser 10-1 according to example 1 of the embodiment of the present technology includes the first and second reflection mirrors 102 and 108, and the semiconductor structure SS that is disposed between the first and second reflection mirrors 102 and 108, the semiconductor structure SS internally includes the convex-shaped part CSP to which the current constriction region is set, and that protrudes toward the second reflection mirror 108 side, and includes the lens-shaped part LSP that meets the convex-shaped part CSP on the top layer on the second reflection mirror 108 side.

In this case, at, for example, a time of manufacturing of the surface emitting laser 10-1, it is possible to laminate a layer that is the material of the lens-shaped part LSP on the layer provided with the convex-shaped part CSP to which the current constriction region is set, and form in this layer the lens-shaped part LSP that meets the convex-shaped part CSP. That is, the convex-shaped part CSP is substantially the underlayer of the lens-shaped part LSP. That is, in the surface emitting laser 10-1, the center of the convex-shaped part CSP and the center of the lens-shaped part substantially match in plan view. Consequently, it is not necessary to adjust the positions of the convex-shaped part CSP and the lens-shaped part LSP.

As a result, according to the surface emitting laser 10-1, it is possible to suppress position shift between the center of the current constriction region and the center of the lens-shaped part in plan view. Consequently, it is possible to reduce the diffraction loss.

The lens-shaped part LSP protrudes toward the second reflection mirror 108 side, and the second reflection mirror 108 is the concave mirror that is provided along the lens-shaped part LSP. Consequently, the concave mirror can reduce the diffraction loss, so that it is possible to increase the resonator length and achieve a high output.

The convex-shaped part CSP has the lens shape. Consequently, only by laminating the layer that is the material of the lens-shaped part LSP on the layer provided with the convex-shaped part CSP, it is possible to form the lens-shaped part LSP.

The convex-shaped part CSP includes the tunnel junction layer 106.

Consequently, it is possible to provide the current constriction function and the light constriction function to the convex-shaped part CSP.

The convex-shaped part CSP includes the cap layer 107a that is laminated on the tunnel junction layer 106 and constitutes at least the top part of the convex-shaped part CSP. Consequently, it is possible to adjust the height of the convex-shaped part CSP (the height of the lens-shaped part LSP) while setting the thickness of the tunnel junction layer 106 to an appropriate value.

The cap layer 107a is made of the same material as that of the top layer (second semiconductor layer 107) on the second reflection mirror 108 side of the semiconductor structure SS. Consequently, it is possible to achieve continuity of the material at the interface of the cap layer 107a and the top layer.

The semiconductor structure SS includes the active layer 104 that is disposed on the first reflection mirror 102 side of the convex-shaped part CSP, the first semiconductor layer 105 that is disposed between the convex-shaped part CSP and the active layer 104, and the second semiconductor layer 107 that buries surroundings of the convex-shaped part CSP and includes the lens-shaped part LSP.

The thickness of the portion of the first semiconductor layer 105 that does not meet the convex-shaped part CSP may be thinner than the thickness of the portion that meets the convex-shaped part CSP.

The tunnel junction layer 106 may include the p-type semiconductor region 106a and the n-type semiconductor region 106b that are mutually laminated, and at least one of the p-type semiconductor region 106a and the n-type semiconductor region 106b may be made of InP or may be made of AlGaInAs.

The first reflection mirror 102 may be a semiconductor multilayer film reflection mirror.

The manufacturing method for the surface emitting laser 10-1 includes: a process of laminating a plurality of semiconductor layers on the substrate 101, and generating the laminated body; a process of forming the resist R of the lens shape on the laminated body; etching the laminated body using the resist R as the mask, and forming the convex-shaped part CSP of the lens shape; laminating the buried layer (second semiconductor layer 107) on the laminated body in which the convex-shaped part CSP has been formed, and forming in the buried layer the lens-shaped part LSP that meets the convex-shaped part CSP; and forming the reflection mirror (second reflection mirror 108) on the lens-shaped part LSP.

According to the manufacturing method for the surface emitting laser 10-1, it is possible to manufacture the surface emitting laser that can suppress position shift between the center of the current constriction region and the center of the lens-shaped part in plan view.

By the way, a Buried Tunnel Junction (BTJ) that has been developed for an eye-safe VCSEL has conventionally been made by processing a tunnel junction layer (including part of n-InP, too) in a circular shape in plan view using wet etching, and regrowing n-InP. On the other hand, the surface emitting laser 10-1 according to example 1 enables simultaneous formation of the aperture and the lens-shaped part by processing at least the tunnel junction layer into the lens shape by dry etching, and burying the tunnel junction layer with n-InP. Consequently, it is unnecessary to align the center of the aperture and the center of the lens-shaped part in plan view, and match these centers at all times. Consequently, it is possible to eliminate occurrence of diffraction loss due to misalignment, and it is possible to expect multiple effects such as a lower threshold, high efficiency, and improvement of a yield rate. Furthermore, according to the surface emitting laser 10-1, lateral mode control can be performed by changing the curvature radius of the lens-shaped part, and all of the first reflection mirror 102 on a substrate 101 side to the second reflection mirror 108 on the surface side are made by crystal growth, so that it is not necessary to control a substrate thickness by polishing or the like and it is also easy to control the resonator length, and, moreover, the concave mirror that is the second reflection mirror 108 can suppress diffraction loss and, consequently, it is also possible to expect an effect of narrowing pitches at a time of array arrangement.

Although part of effects will be repeatedly described, the surface emitting laser 10-1 can also obtain following effects (1) to (15).

(1) It is unnecessary to align the aperture and the lens-shaped part, so that it is possible to eliminate diffraction loss due to misalignment in an intra-planar direction.

(2) The concave mirror can reduce the diffraction loss, so that it is easy to increase the resonator length, and it is possible to achieve high power.

(3) It is not necessary to polish a wafer, so that it is possible to control the resonator length based only on an epitaxial layer thickness.

(4) It is possible to narrow a pitch of an emitter (light emitting unit), so that it is easy to narrow pitches when an array is formed.

(5) It is possible to perform lateral mode control by changing the curvature radius.

(6) The face (the surface of the lens-shaped part LSP) on which the second reflection mirror is formed is not a face to be dry-etched or polished, so that it is possible to achieve low roughness and it is also possible to reduce scattering loss due to roughness of the second reflection mirror.

(7) The convex-shaped part is processed by dry etching, so that it is possible to reduce the number of processes.

(8) The convex-shaped part is processed by dry etching, so that side etching that is performed at a time of wet etching is not performed, and a void after regrowth is not produced, either.

(9) The convex-shaped part is processed by dry etching, so that, even when, for example, a substrate having asymmetrical faces is used, a crystal plane does not appear, and it is possible to form a symmetrical and uniform aperture.

(10) When the aperture diameter d and the curvature radius R are changed by design, it is also possible to easily change the height of the lens-shaped part by crystal growth.

(11) It is possible to increase the resonator length (increase the thickness), so that it easy to process the back surface.

(12) Although current constriction caused by ion implantation that is usually used for concave mirror-type VCSELs scatters light in an ion implantation region when a beam waist is large, the surface emitting laser 10-1 does not cause such scattering loss.

(13) The diffraction loss is reduced, so that it is possible to achieve a lower threshold.

(14) The diffraction loss is reduced, so that it is also possible to achieve high efficiency.

(15) The diffraction loss is reduced, so that it is possible to improve the yield rate.

### <2. Surface Emitting Laser According to Example 2 of Embodiment of Present Technology>

### <<Configuration of Surface Emitting Laser>>

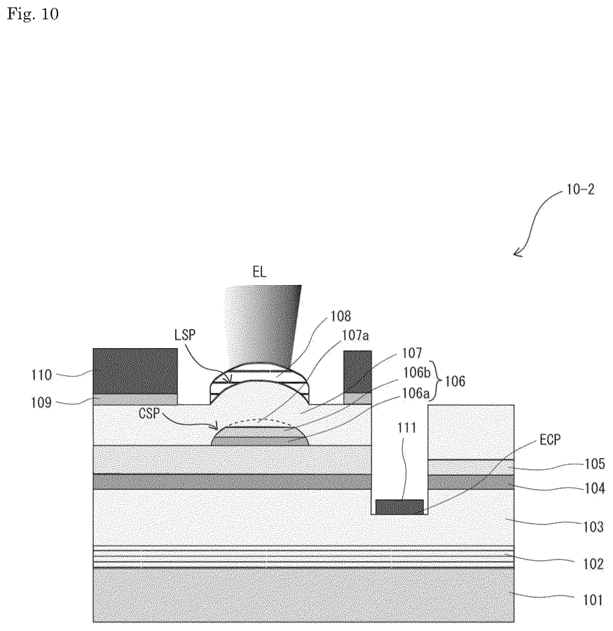

FIG. 10 is a cross-sectional view of a surface emitting laser 10-2 according to example 2 of the embodiment of the present technology. The surface emitting laser 10-2 employs substantially the same configuration as that of the surface emitting laser 10-1 according to example 1 except that the material of the n-type semiconductor region 106b of the tunnel junction layer 106 is different as illustrated in FIG. 10.

According to the surface emitting laser 10-2, the n-type semiconductor region 106b of the tunnel junction layer 106 is made of n-AlGaInAs that is doped with, for example, Si or Te of a high concentration.

Although the bump is not provided near the tunnel junction layer 106 of the first semiconductor layer 105 in the surface emitting laser 10-2, a bump formed by over etching may be provided similarly to the surface emitting laser 10-1 according to example 1.

### <<Operation of and Manufacturing Method for Surface Emitting Laser>>

The surface emitting laser 10-2 can perform the same operation and be manufactured by the same manufacturing method as those of the surface emitting laser 10-1 according to example 1.

### <<Effect of Surface Emitting Laser and Manufacturing Method for Surface Emitting Laser>>

According to the surface emitting laser 10-2, it is possible to obtain the same effect as that of the surface emitting laser 10-1 according to example 1.

According to the manufacturing method for the surface emitting laser 10-2, it is possible to obtain the same effect as that of the manufacturing method for the surface emitting laser 10-1 according to example 1.

### <3. Surface Emitting Laser According to Example 3 of Embodiment of Present Technology>

### <<Configuration of Surface Emitting Laser>>

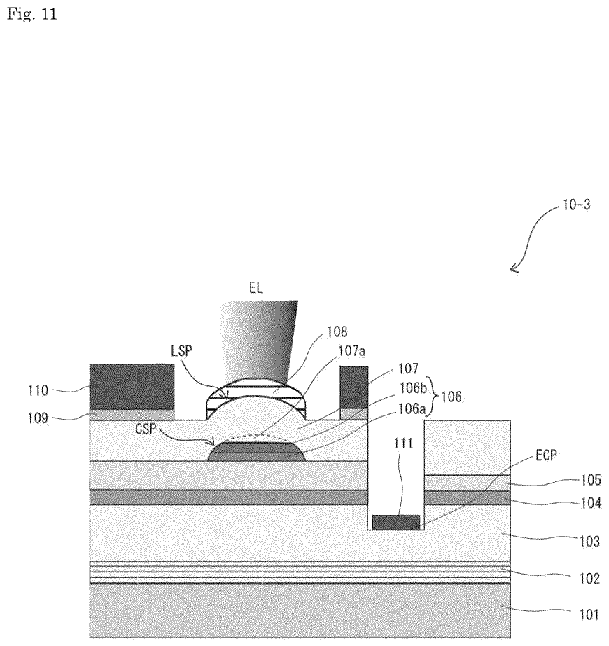

FIG. 11 is a cross-sectional view of a surface emitting laser 10-3 according to example 3 of the embodiment of the present technology. The surface emitting laser 10-3 employs substantially the same configuration as that of the surface emitting laser 10-1 according to example 1 except that the material of the p-type semiconductor region 106a of the tunnel junction layer 106 is different as illustrated in FIG. 11.

According to the surface emitting laser 10-3, the p-type semiconductor region 106a of the tunnel junction layer 106 is made of n-InP that is doped with, for example, C, Mg, or Zn of a high concentration.

Although the bump is not provided near the tunnel junction layer 106 of the first semiconductor layer 105 in the surface emitting laser 10-3, a bump formed by over etching may be provided similarly to the surface emitting laser 10-1 according to example 1.

### <<Operation of and Manufacturing Method for Surface Emitting Laser>>

The surface emitting laser 10-3 can perform the same operation and be manufactured by the same manufacturing method as those of the surface emitting laser 10-1 according to example 1.

### <<Effect of Surface Emitting Laser and Manufacturing Method for Surface Emitting Laser>>

According to the surface emitting laser 10-3, it is possible to obtain the same effect as that of the surface emitting laser 10-1 according to example 1. According to the manufacturing method for the surface emitting laser 10-3, it is possible to obtain the same effect as that of the manufacturing method for the surface emitting laser 10-1 according to example 1.

### <4. Surface Emitting Laser According to Example 4 of Embodiment of Present Technology>

### <<Configuration of Surface Emitting Laser>>

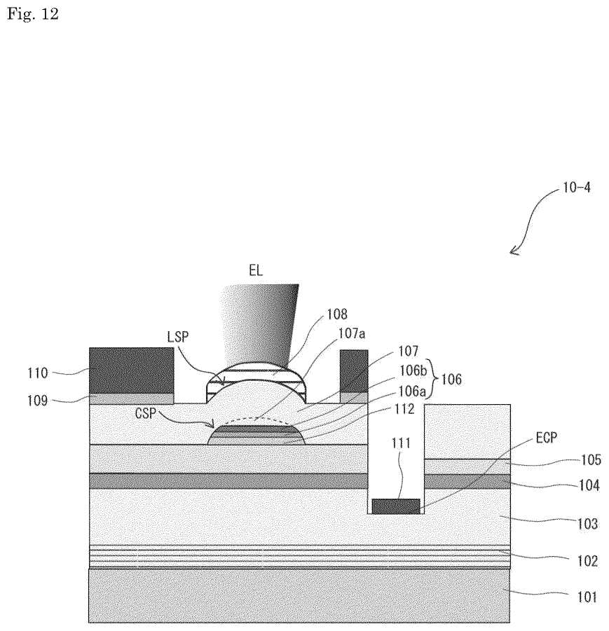

FIG. 12 is a cross-sectional view of a surface emitting laser 10-4 according to example 4 of the embodiment of the present technology. The surface emitting laser 10-4 employs the same configuration as that of the surface emitting laser 10-3 according to example 3 except that the convex-shaped part CSP includes a spacer layer 112 that constitutes at least a bottom part as illustrated in FIG. 12.

The spacer layer 112 is disposed on the active layer 104 side of the p-type semiconductor region 106a. The spacer layer 112 also contributes to adjusting the height of the convex-shaped part CSP similarly to the cap layer 107a. The spacer layer 112 is preferably made of a material (e.g., p-AlGaInAs) that can reduce characteristics change between the neighboring p-type semiconductor regions 106a.

Although the bump is not provided near the tunnel junction layer 106 of the first semiconductor layer 105 in the surface emitting laser 10-4, a bump formed by over etching may be provided similarly to the surface emitting laser 10-1 according to example 1.

### <<Operation of and Manufacturing Method for Surface Emitting Laser>>

The surface emitting laser 10-4 can perform the same operation and be manufactured by the same manufacturing method as those of the surface emitting laser 10-1 according to example 1.

### <<Effect of Surface Emitting Laser and Effect of Manufacturing Method for Surface Emitting Laser>>

According to the surface emitting laser 10-4, it is possible to obtain the same effect as that of the surface emitting laser 10-1 according to example 1.

According to the manufacturing method for the surface emitting laser 10-4, it is possible to obtain the same effect as that of the manufacturing method for the surface emitting laser 10-1 according to example 1.

### <5. Surface Emitting Laser According to Example 5 of Embodiment of Present Technology>

### <<Configuration of Surface Emitting Laser>>

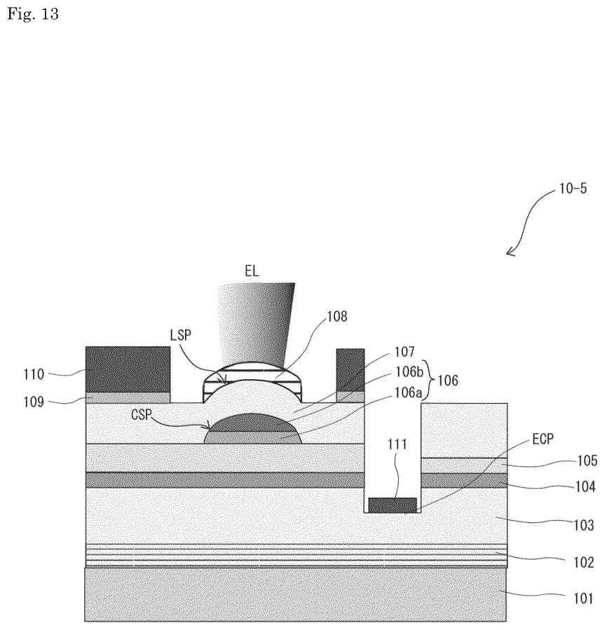

FIG. 13 is a cross-sectional view of a surface emitting laser 10-5 according to example 5 of the embodiment of the present technology. The surface emitting laser 10-5 employs substantially the same configuration as that of the surface emitting laser 10-1 according to example 1 except that the convex-shaped part CSP includes only the tunnel junction layer 106 as illustrated in FIG. 13.

Although the bump is not provided near the tunnel junction layer 106 of the first semiconductor layer 105 in the surface emitting laser 10-5, a bump formed by over etching may be provided similarly to the surface emitting laser 10-1 according to example 1.

### <<Operation of Surface Emitting Laser>>

The surface emitting laser 10-5 performs the same operation as that of the surface emitting laser 10-1 according to example 1.

### <<Manufacturing Method for Surface Emitting Laser>>

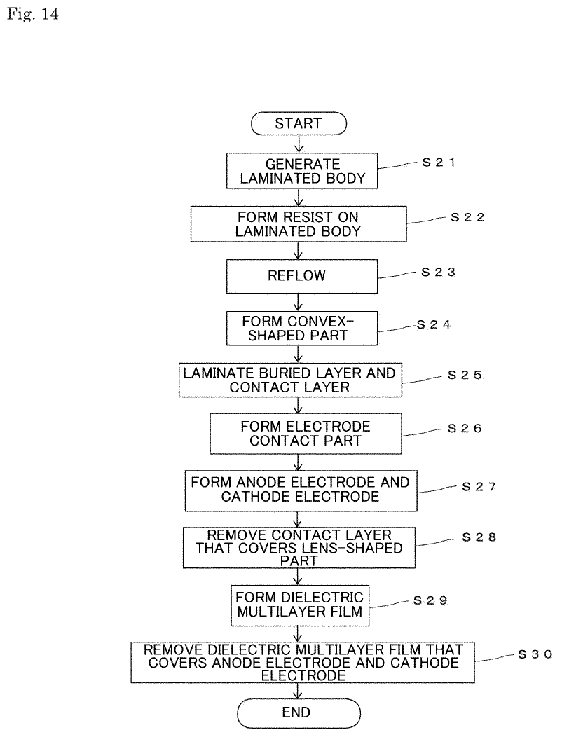

Hereinafter, the manufacturing method for the surface emitting laser 10-5 will be described with reference to the flowchart in FIG. 14 or the like. Here, for example, the semiconductor manufacturing method that uses the semiconductor manufacturing device simultaneously generates a plurality of the surface emitting lasers 10-5 on one wafer that is the base material of the substrate 101. Next, a series of the plurality of integrated surface emitting lasers 10-5 are separated to obtain the plurality of chip-shaped surface emitting lasers 10-5 (surface emitting laser chips).

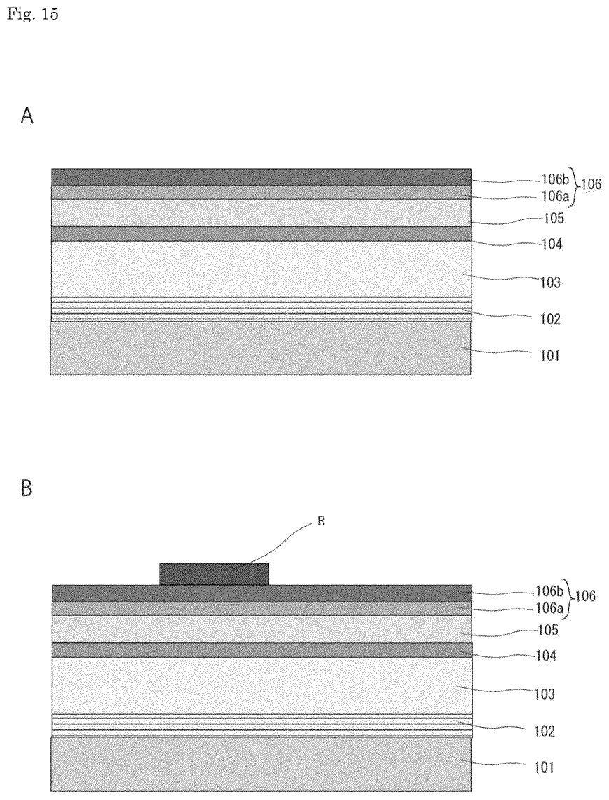

In first step S21, a laminated body is generated (see FIG. 15A). More specifically, the first reflection mirror 102, the third semiconductor layer 103, the active layer 104, the first semiconductor layer 105, and the tunnel junction layer 106 are grown in this order on the substrate 101 (e.g., InP substrate) by, for example, the Metal Organic Chemical Vapor Deposition method (MOCVD method).

In next step S22, the resist R is formed on the laminated body (see FIG. 15B). More specifically, first, the resist is applied to the entire surface of the laminated body. Next, the resist is exposed to light with the mask interposed therebetween to form the resist R (resist pattern) that covers only the portion at which the convex-shaped part CSP of the laminated body is to be formed.

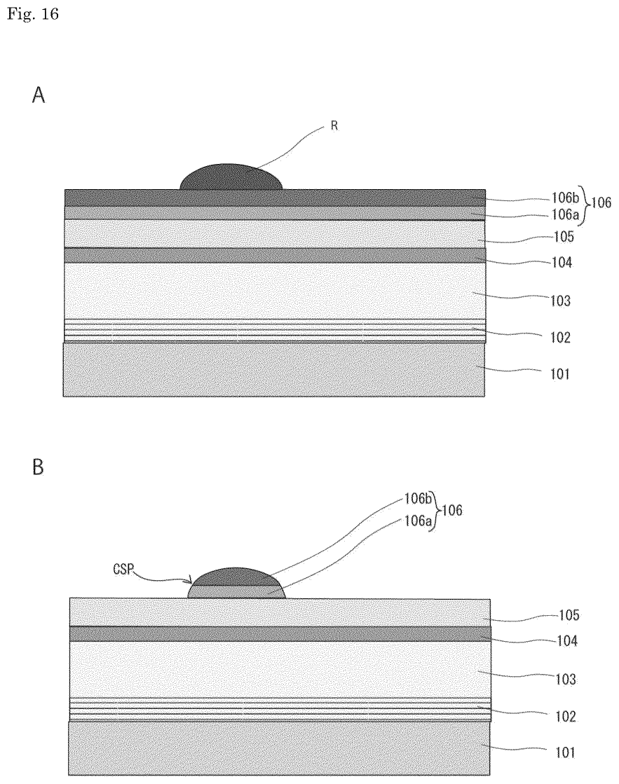

In next step S23, reflow (heating treatment) is performed (see FIG. 16A). More specifically, reflow is performed at, for example, 200° C. in temperature to hold up the resist R.

In next step S24, the convex-shaped part CSP is formed (see FIG. 16B). More specifically, by performing dry etching using the resist R as the mask, the shape of the resist R is transferred to the laminated body to form the convex-shaped part CSP.

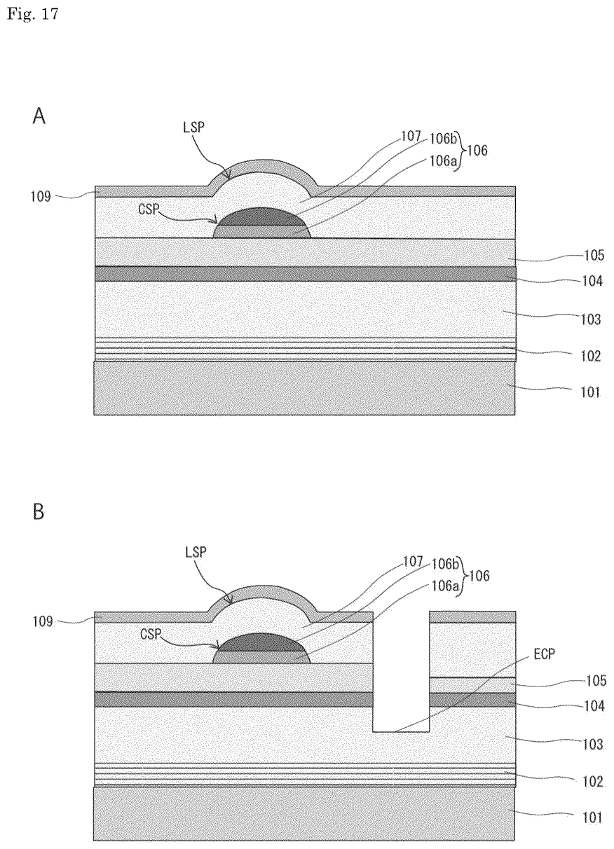

In next step S25, the second semiconductor layer 107 and the contact layer 109 that are the buried layers are laminated (see FIG. 17A). More specifically, the second semiconductor layer 107 and the contact layer 109 that are the buried layers are regrown in this order on the laminated body on which the convex-shaped part CSP has been formed, by, for example, the Metal Organic Chemical Vapor Deposition method (MOCVD method) to form the BTJ. As a result, the lens-shaped part LSP that meets the convex-shaped part CSP (the lens-shaped part LSP that goes along the convex-shaped part CSP) is formed in the second semiconductor layer 107.

In next step S26, the electrode contact part ECP is formed (see FIG. 17B). More specifically, the laminated body in which the second semiconductor layer 107 and the contact layer 109 have been formed is etched to form the electrode contact part ECP.

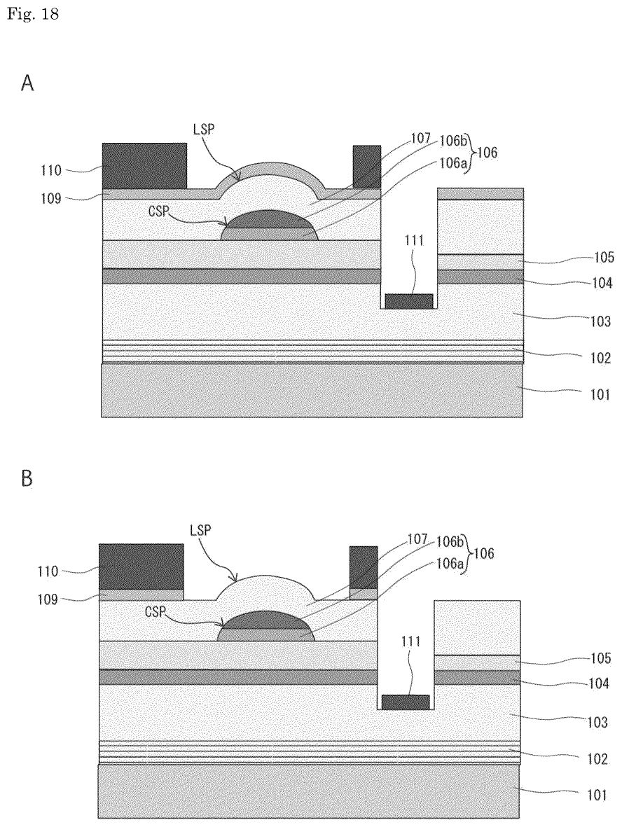

In next step S27, the anode electrode 110 and the cathode electrode 111 are formed (see FIG. 18A). More specifically, the anode electrode 110 of the circular shape is formed by, for example, the lift-off method so as to surround the lens-shaped part LSP on the laminated body, and the cathode electrode 111 is formed at the electrode contact part ECP.

In next step S28, the contact layer 109 that covers the lens-shaped part LSP is removed (see FIG. 18B). More specifically, a resist pattern that is opened on the portion that covers at least the lens-shaped part LSP of the contact layer 109 is formed on the laminated body, and the laminated body is etched using the resist pattern as the mask to remove the contact layer 109 that covers the lens-shaped part LSP and exposes the lens-shaped part LSP.

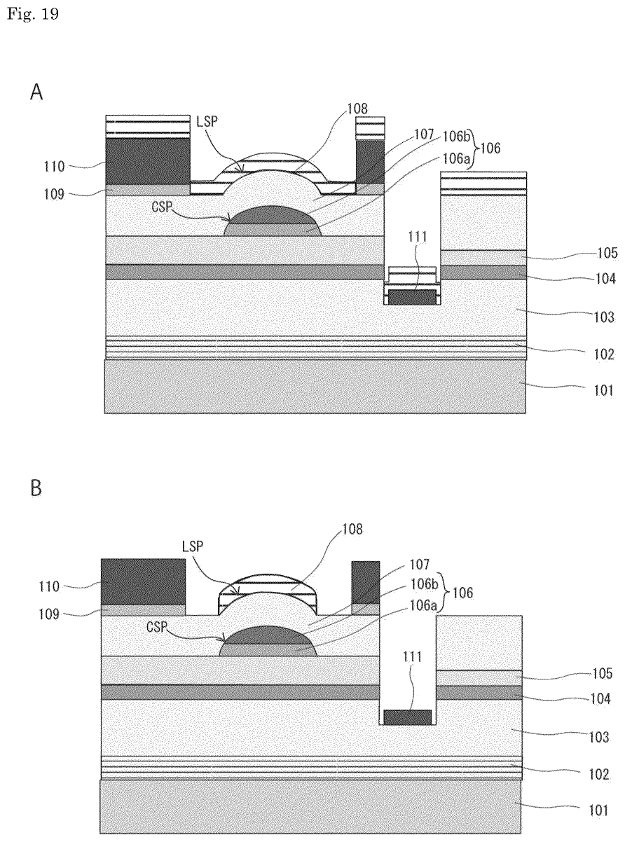

In next step S29, a dielectric multilayer film is formed (see FIG. 19A). More specifically, the dielectric multilayer film that is the material of the second reflection mirror 108 is formed on the entire surface of the laminated body from which the lens-shaped part LSP has been exposed.

In last step S30, the dielectric multilayer film that covers the anode electrode 110 and the cathode electrode 111 is removed (see FIG. 19B). More specifically, the resist pattern that covers the dielectric multilayer film on the lens-shaped part LSP is formed on the laminated body, and the dielectric multilayer film is etched using the resist pattern as the mask. As a result, only the dielectric multilayer film on the lens-shaped part LSP remains as the second reflection mirror 108.

### <<Effect of Surface Emitting Laser and Effect of Manufacturing Method for Surface Emitting Laser>>

According to the surface emitting laser 10-5, it is possible to obtain substantially the same effect as that of the surface emitting laser 10-1 according to example 1, and, it is possible to simplify a layer configuration of the convex-shaped part CSP while the degree of freedom of design of the height of the convex-shaped part CSP is low due to constraint of the thickness (appropriate value) of the tunnel junction layer 106. According to the manufacturing method for the surface emitting laser 10-5, it is possible to obtain the same effect as that of the manufacturing method for the surface emitting laser 10-1 according to example 1.

### <6. Surface Emitting Laser According to Example 6 of Embodiment of Present Technology>

### <<Configuration of Surface Emitting Laser>>

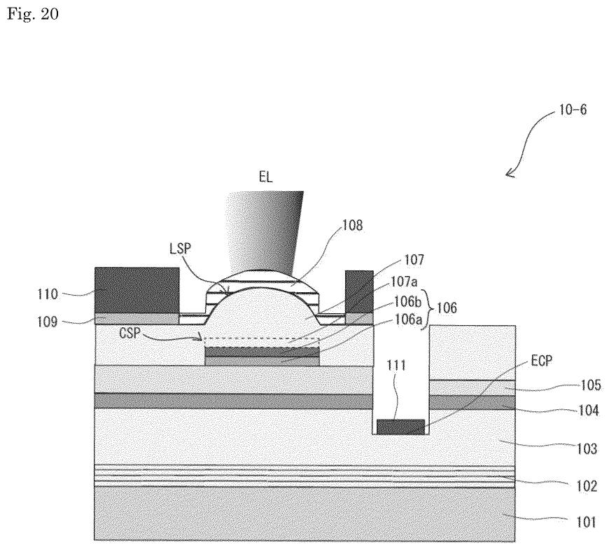

FIG. 20 is a cross-sectional view of a surface emitting laser 10-6 according to example 6 of the embodiment of the present technology. The surface emitting laser 10-6 employs substantially the same configuration as that of the surface emitting laser 10-1 according to example 1 except that the convex-shaped part CSP has a mesa shape as illustrated in FIG. 20.

According to the surface emitting laser 10-6, for example, the convex-shaped part CSP that includes the tunnel junction layer 106 and the cap layer 107a has the mesa shape of a rectangular longitudinal cross-section.

Although the bump is not provided near the tunnel junction layer 106 of the first semiconductor layer 105 in the surface emitting laser 10-6, a bump formed by over etching may be provided similarly to the surface emitting laser 10-1 according to example 1.

### <<Operation of Surface Emitting Laser>>

The surface emitting laser 10-6 performs the same operation as that of the surface emitting laser 10-1 according to example 1.

### <<Manufacturing Method for Surface Emitting Laser>>

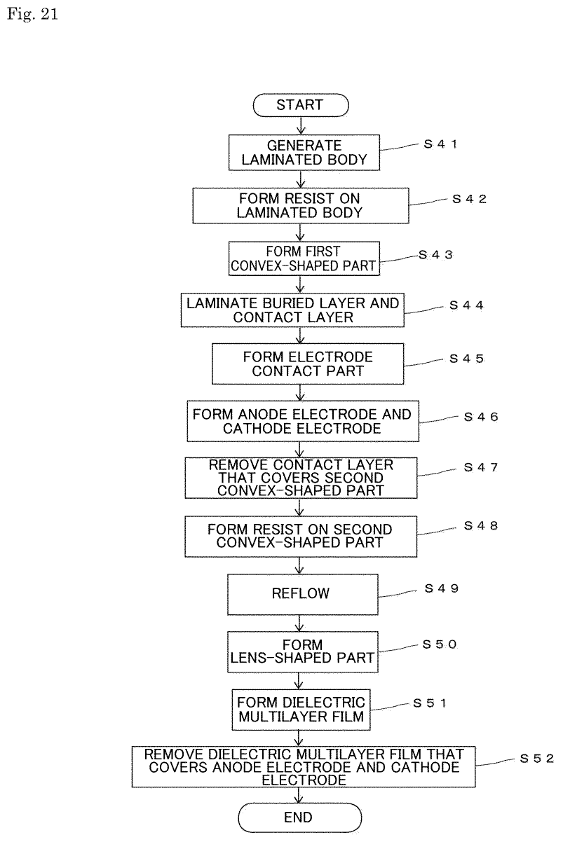

Hereinafter, the manufacturing method for the surface emitting laser 10-6 will be described with reference to the flowchart in FIG. 21 or the like. Here, for example, the semiconductor manufacturing method that uses the semiconductor manufacturing device simultaneously generates a plurality of the surface emitting lasers 10-6 on one wafer that is the base material of the substrate 101. Next, a series of the plurality of integrated surface emitting lasers 10-6 are separated to obtain the plurality of chip-shaped surface emitting lasers 10-6 (surface emitting laser chips).

In first step S41, the laminated body is generated (see FIG. 5A). More specifically, the first reflection mirror 102, the third semiconductor layer 103, the active layer 104, the first semiconductor layer 105, the tunnel junction layer 106, and the cap layer 107a are grown in this order on the substrate 101 (e.g., InP substrate) by, for example, the Metal Organic Chemical Vapor Deposition method (MOCVD method).

In next step S42, the resist R is formed on the laminated body (see FIG. 5B). More specifically, first, the resist is applied to the entire surface of the laminated body. Next, the resist is exposed to light with the mask interposed therebetween to form the resist R (resist pattern) that covers only the portion at which the convex-shaped part CSP of the laminated body is to be formed.

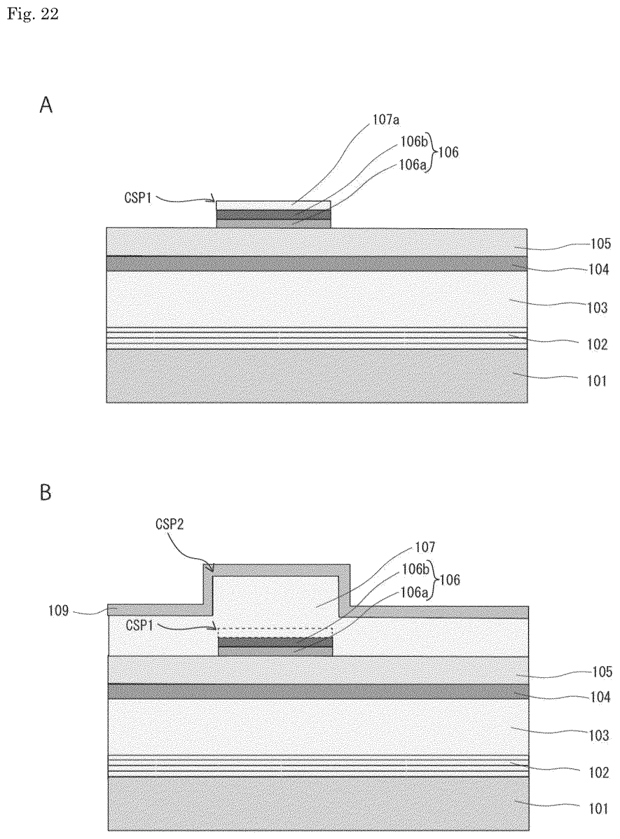

In next step S43, a first convex-shaped part CSP1 (convex-shaped part CP) is formed (see FIG. 22A). More specifically, by performing etching using the resist R as the mask, the shape (e.g., rectangular longitudinal cross-sectional shape) of the resist R is transferred to the laminated body to form the first convex-shaped part CSP1.

In next step S44, the second semiconductor layer 107 and the contact layer 109 that are the buried layers are laminated (see FIG. 22B). More specifically, the second semiconductor layer 107 and the contact layer 109 that are the buried layers are regrown in this order on the laminated body on which the convex-shaped part CSP has been formed, by, for example, the Metal Organic Chemical Vapor Deposition method (MOCVD method) to form the BTJ. As a result, the second convex-shaped part CSP2 that meets the first convex-shaped part CSP1 (the convex-shaped part that goes along the first convex-shaped part CSP1) is formed in the second semiconductor layer 107.

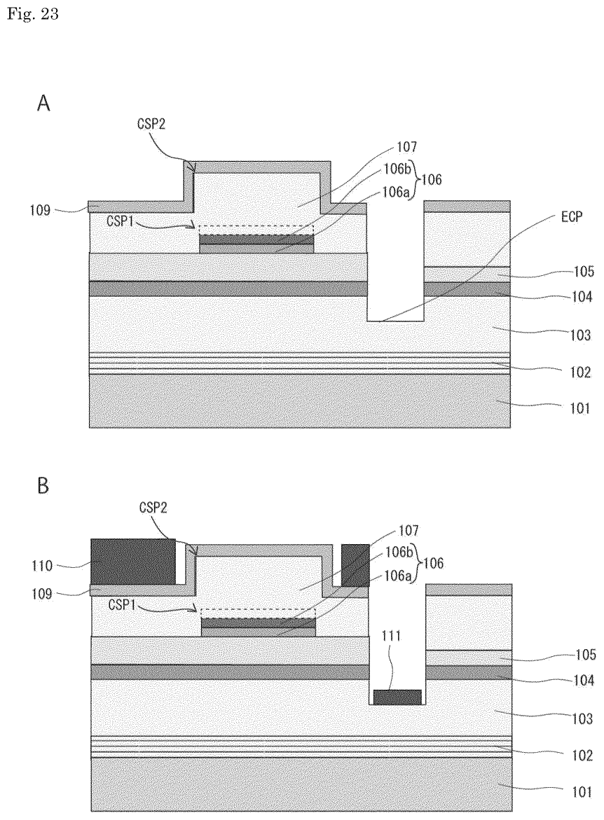

In next step S45, the electrode contact part ECP is formed (see FIG. 23A). More specifically, the laminated body in which the second semiconductor layer 107 and the contact layer 109 have been laminated is etched to form the electrode contact part ECP.

In next step S46, the anode electrode 110 and the cathode electrode 111 are formed (see FIG. 23B). More specifically, the anode electrode 110 of the circular shape is formed by, for example, the lift-off method so as to surround the lens-shaped part LSP on the laminated body, and the cathode electrode 111 is formed at the electrode contact part ECP.

In next step S47, the contact layer 109 that covers the second convex-shaped part CSP2 is removed (see FIG. 24A). More specifically, a resist pattern that is opened on the portion that covers at least the second convex-shaped part CSP of the contact layer 109 is formed on the laminated body, and the laminated body is etched using the resist pattern as the mask to remove the contact layer 109 that covers the second convex-shaped part CSP2 and exposes the second convex-shaped part CSP2.

In next step S48, the resist R is formed on the second convex-shaped part CSP2 (see FIG. 24B). More specifically, first, the resist is applied to the entire surface of the laminated body. Next, the resist is exposed to light with the mask interposed therebetween to form the resist R (resist pattern) that covers only the portion at which the lens-shaped part LSP of the second convex-shaped part CSP2 is to be formed.

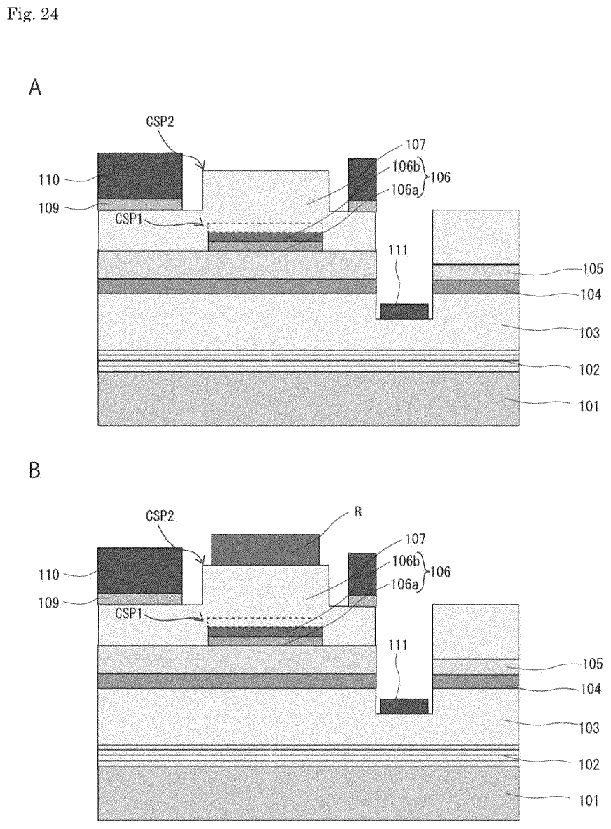

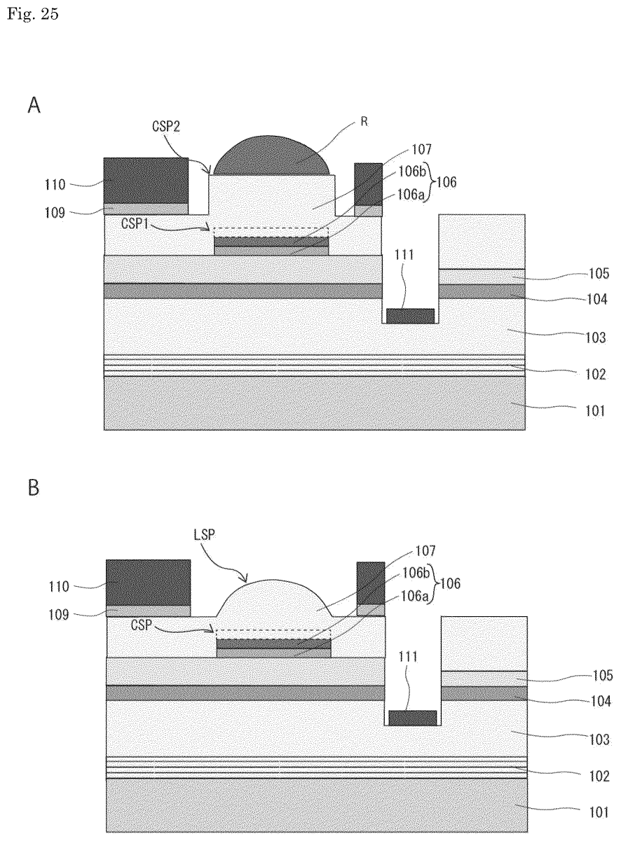

In next step S49, reflow (heating treatment) is performed (see FIG. 25A). More specifically, reflow is performed at, for example, 200° C. in temperature to hold up the resist R.

In next step S50, the lens-shaped part LSP is formed (see FIG. 25B). More specifically, by etching the second convex-shaped part CSP2 using the resist R as the mask, the shape of the resist R is transferred to the second convex-shaped part CSP2 to form the lens-shaped part LSP.

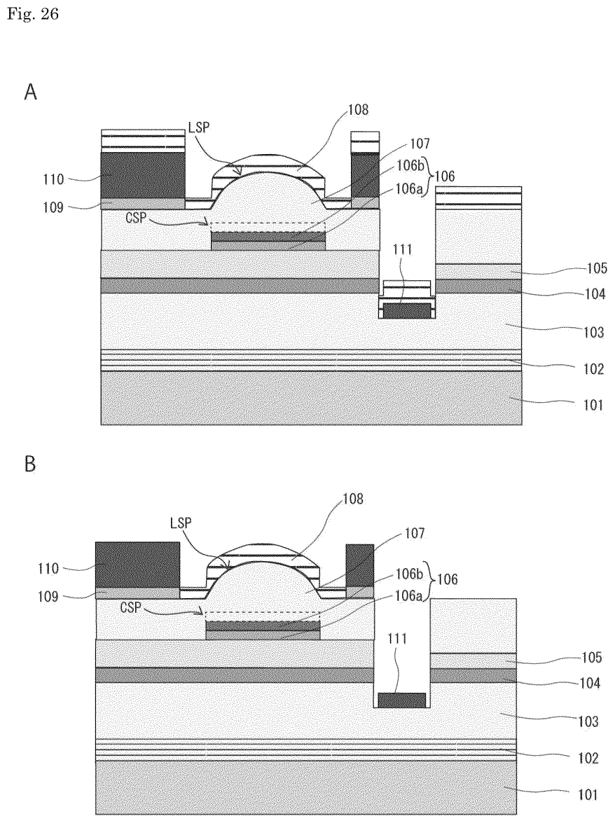

In next step S51, a dielectric multilayer film is formed (see FIG. 26A). More specifically, the dielectric multilayer film that is the material of the second reflection mirror 108 is formed on the entire surface of the laminated body from which the lens-shaped part LSP has been exposed.

In last step S52, the dielectric multilayer film that covers the anode electrode 110 and the cathode electrode 111 is removed (see FIG. 26B). More specifically, the resist pattern that covers the dielectric multilayer film on the lens-shaped part LSP is formed on the laminated body, and the dielectric multilayer film is etched using the resist pattern as the mask. As a result, only the dielectric multilayer film on the lens-shaped part LSP remains as the second reflection mirror 108.

### <<Effect of Surface Emitting Laser and Effect of Manufacturing Method for Surface Emitting Laser>>

According to the surface emitting laser 10-6, it is possible to obtain substantially the same effect as that of the surface emitting laser 10-1 according to example 1. According to the manufacturing method for the surface emitting laser 10-6, it is possible to obtain substantially the same effect even though the number of processes increases to some degree compared to the manufacturing method for the surface emitting laser 10-1 according to example 1.

### <7. Surface Emitting Laser According to Example 7 of Embodiment of Present Technology>

### <<Configuration of Surface Emitting Laser>>

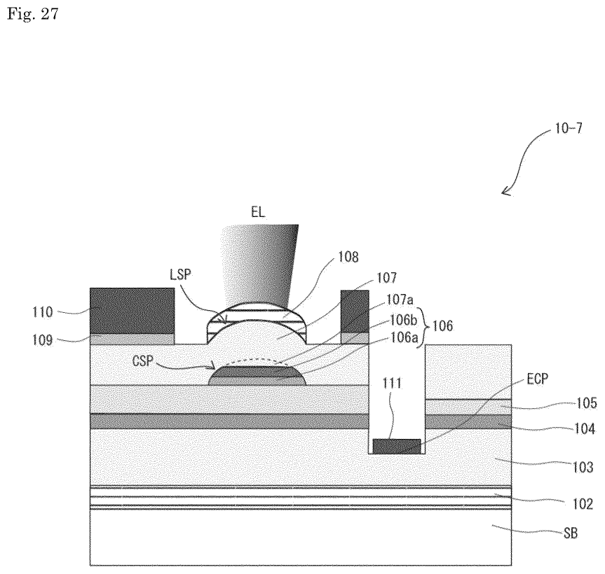

FIG. 27 is a cross-sectional view of a surface emitting laser 10-7 according to example 7 of the embodiment of the present technology. The surface emitting laser 10-7 employs the same configuration as that of the surface emitting laser 10-1 according to example 1 except that the surface emitting laser 10-7 includes a support base SB instead of the substrate 101 (growth substrate), and the first reflection mirror 102 is a dielectric multilayer film reflection mirror.

Although the bump is not provided near the tunnel junction layer 106 of the first semiconductor layer 105 in the surface emitting laser 10-7, a bump formed by over etching may be provided similarly to the surface emitting laser 10-1 according to example 1.

### <<Operation of Surface Emitting Laser>>

The surface emitting laser 10-7 performs the same operation as that of the surface emitting laser 10-1 according to example 1.

### <<Manufacturing Method for Surface Emitting Laser>>

The manufacturing method for the surface emitting laser 10-7 will be briefly described. First, the third semiconductor layer 103, the active layer 104, the first semiconductor layer 105, the tunnel junction layer 106, the second semiconductor layer 107, the second reflection mirror 108, and the like are formed on the substrate 101 (growth substrate), then a temporary support base is pasted on the second reflection mirror 108 side, and the substrate 101 (growth substrate) is removed. Next, the dielectric multilayer film reflection mirror that is the first reflection mirror 102 is formed on the back surface of the third semiconductor layer 103. Next, the support base SB is pasted on the back surface of the first reflection mirror 102, and then the temporary support base is removed.

### <<Effect of Surface Emitting Laser and Manufacturing Method for Surface Emitting Laser>>

According to the surface emitting laser 10-7, the dielectric multilayer film reflection mirror that can achieve high reflectance using a smaller number of pairs is used as the first reflection mirror 102, so that it is easy to achieve a high output. According to the manufacturing method for the surface emitting laser 10-7, it is possible to obtain substantially the same effect as that of the manufacturing method for the surface emitting laser 10-1 according to example 1.

### <8. Surface Emitting Laser According to Example 8 of Embodiment of Present Technology>

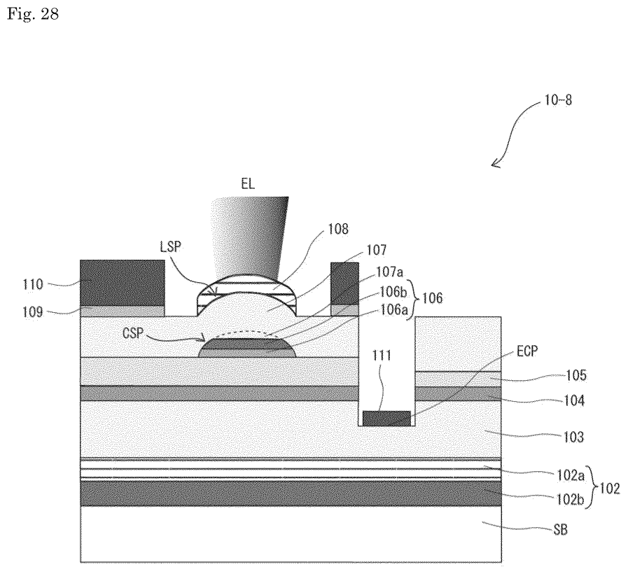

FIG. 28 is a cross-sectional view of a surface emitting laser 10-8 according to example 8 of the embodiment of the present technology. The surface emitting laser 10-8 employs the same configuration as that of the surface emitting laser 10-1 according to example 1 except that the surface emitting laser 10-8 includes the support base SB instead of the substrate 101 (growth substrate), and the first reflection mirror 102 is a hybrid mirror that includes a dielectric multilayer film reflection mirror 102a and a metal reflection mirror 102b. Examples of a material of the metal reflection mirror 102b include Au, Ag, Cu, and Al.

Although the bump is not provided near the tunnel junction layer 106 of the first semiconductor layer 105 in the surface emitting laser 10-8, a bump formed by over etching may be provided similarly to the surface emitting laser 10-1 according to example 1.

### <<Operation of Surface Emitting Laser>>

The surface emitting laser 10-8 performs the same operation as that of the surface emitting laser 10-1 according to example 1.

### <<Manufacturing Method for Surface Emitting Laser>>

The manufacturing method for the surface emitting laser 10-8 will be briefly described. Next, the third semiconductor layer 103, the active layer 104, the first semiconductor layer 105, the tunnel junction layer 106, the second semiconductor layer 107, the second reflection mirror 108, and the like are formed on the substrate 101 (growth substrate), then a temporary support base is pasted on the second reflection mirror 108 side, and the substrate 101 (growth substrate) is removed. Next, the dielectric multilayer film reflection mirror 102a that is the first reflection mirror 102 is formed on the back surface of the third semiconductor layer 103. Next, the metal reflection mirror 102b is formed on the back surface of the dielectric multilayer film reflection mirror 102a. Next, the support base SB is pasted on the back surface of the metal reflection mirror 102b, and then the temporary support base is removed.

### <<Effect of Surface Emitting Laser and Manufacturing Method for Surface Emitting Laser>>

According to the surface emitting laser 10-8, the hybrid mirror including the dielectric multilayer film reflection mirror and the metal reflection mirror is used as the first reflection mirror 102, so that it is possible to obtain high reflectance and improve heat dissipation while preventing the thickness of the first reflection mirror 102 from becoming thicker. According to the manufacturing method for the surface emitting laser 10-8, it is possible to obtain substantially the same effect as that of the manufacturing method for the surface emitting laser 10-1 according to example 1.

### <9. Surface Emitting Laser According to Example 9 of Embodiment of Present Technology>

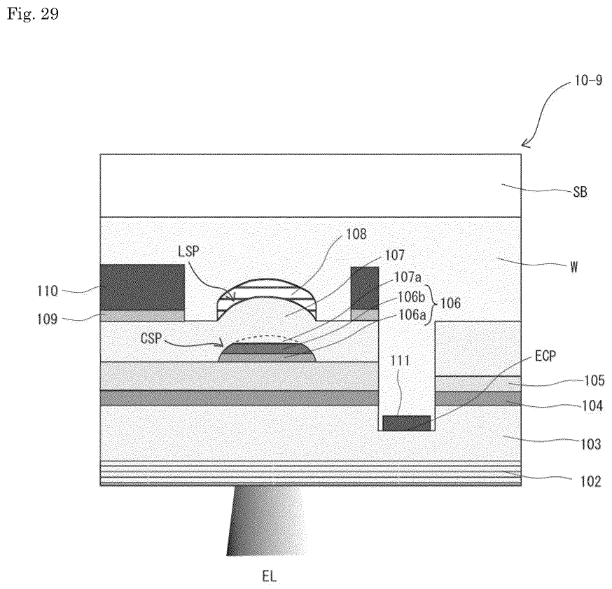

FIG. 29 is a cross-sectional view of a surface emitting laser 10-9 according to example 9 of the embodiment of the present technology. The surface emitting laser 10-9 employs the same configuration as that of the surface emitting laser 10-1 according to example 1 except that the surface emitting laser 10-9 includes the support base SB on the second reflection mirror 108 side instead of the substrate 101 (growth substrate).

In the surface emitting laser 10-9, the support base SB is pasted on the surface on the second reflection mirror 108 side with a wax W interposed therebetween.

In the surface emitting laser 10-9, the back surface (lower surface) of a semiconductor multilayer film reflection mirror that is the first reflection mirror 102 is exposed, and is an emission side reflection mirror. That is, the surface emitting laser 10-9 is a back surface emission-type surface emitting laser.

Although the bump is not provided near the tunnel junction layer 106 of the first semiconductor layer 105 in the surface emitting laser 10-9, a bump formed by over etching may be provided similarly to the surface emitting laser 10-1 according to example 1.

### <<Operation of Surface Emitting Laser>>

The surface emitting laser 10-9 performs the same operation as that of the surface emitting laser 10-1 according to example 1 except that the first reflection mirror 102 emits the emission light EL.

### <<Manufacturing Method for Surface Emitting Laser>>

The manufacturing method for the surface emitting laser 10-9 will be briefly described. First, the third semiconductor layer 103, the active layer 104, the first semiconductor layer 105, the tunnel junction layer 106, the second semiconductor layer 107, the second reflection mirror 108, and the like are formed on the substrate 101 (growth substrate), then the support base SB is pasted on the second reflection mirror 108 side, and the substrate 101 (growth substrate) is removed. As a result, the back surface of the first reflection mirror 102 is exposed.

### <<Effect of Surface Emitting Laser and Manufacturing Method for Surface Emitting Laser>>

According to the surface emitting laser 10-9, it is possible to provide the back surface emission-type surface emitting laser that can obtain the same effect as that of the surface emitting laser 10-1 according to example 1. According to the manufacturing method for the surface emitting laser 10-9, it is possible to substantially obtain the same effect as that of the manufacturing method for the surface emitting laser 10-1 according to example 1.

### <10. Surface Emitting Laser According to Example 10 of Embodiment of Present Technology>

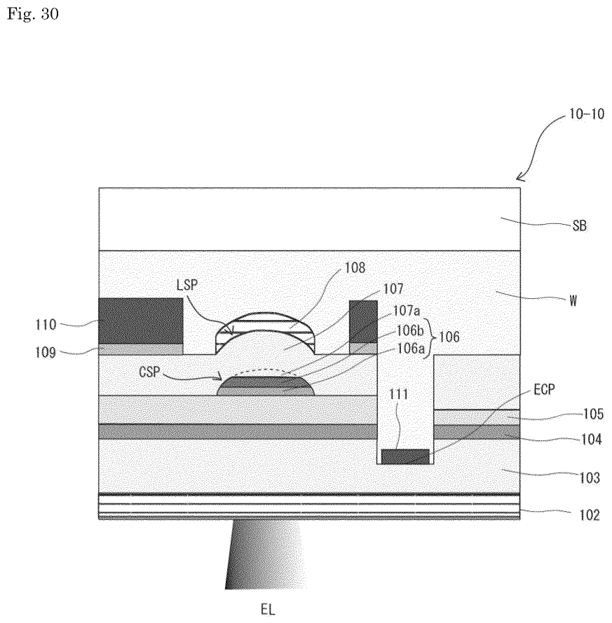

FIG. 30 is a cross-sectional view of a surface emitting laser 10-10 according to example 10 of the embodiment of the present technology. The surface emitting laser 10-10 employs the same configuration as that of the surface emitting laser 10-1 according to example 1 except that the surface emitting laser 10-10 includes the support base SB on the second reflection mirror 108 side instead of the substrate 101 (growth substrate), and the first reflection mirror 102 is a dielectric multilayer film reflection mirror.

In the surface emitting laser 10-10, the support base SB is pasted on the surface on the second reflection mirror 108 side with the wax W interposed therebetween. In the surface emitting laser 10-10, the back surface (lower surface) of a dielectric multilayer film reflection mirror that is the first reflection mirror 102 is exposed, and is an emission side reflection mirror. That is, the surface emitting laser 10-10 is a back surface emission-type surface emitting laser.

Although the bump is not provided near the tunnel junction layer 106 of the first semiconductor layer 105 in the surface emitting laser 10-10, a bump formed by over etching may be provided similarly to the surface emitting laser 10-1 according to example 1.

### <<Operation of Surface Emitting Laser>>

The surface emitting laser 10-10 performs the same operation as that of the surface emitting laser 10-1 according to example 1 except that the first reflection mirror 102 emits the emission light EL.

### <<Manufacturing Method for Surface Emitting Laser>>

The manufacturing method for the surface emitting laser 10-10 will be briefly described. First, the third semiconductor layer 103, the active layer 104, the first semiconductor layer 105, the tunnel junction layer 106, the second semiconductor layer 107, the second reflection mirror 108, and the like are formed on the substrate 101 (growth substrate), then the support base SB is pasted on the second reflection mirror 108 side, and the substrate 101 (growth substrate) is removed. Next, the dielectric multilayer film reflection mirror that is the first reflection mirror 102 is formed on the back surface (lower surface) of the third semiconductor layer 103.

### <<Effect of Surface Emitting Laser and Manufacturing Method for Surface Emitting Laser>>

According to the surface emitting laser 10-10, the dielectric multilayer film reflection mirror that can achieve high reflectance using a smaller number of pairs is used as the first reflection mirror 102, so that it is possible to provide the back surface emission-type surface emitting laser that easily achieves a high output. According to the manufacturing method for the surface emitting laser 10-10, it is possible to obtain substantially the same effect as that of the manufacturing method for the surface emitting laser 10-1 according to example 1.

### <11. Surface Emitting Laser According to Example 11 of Embodiment of Present Technology>

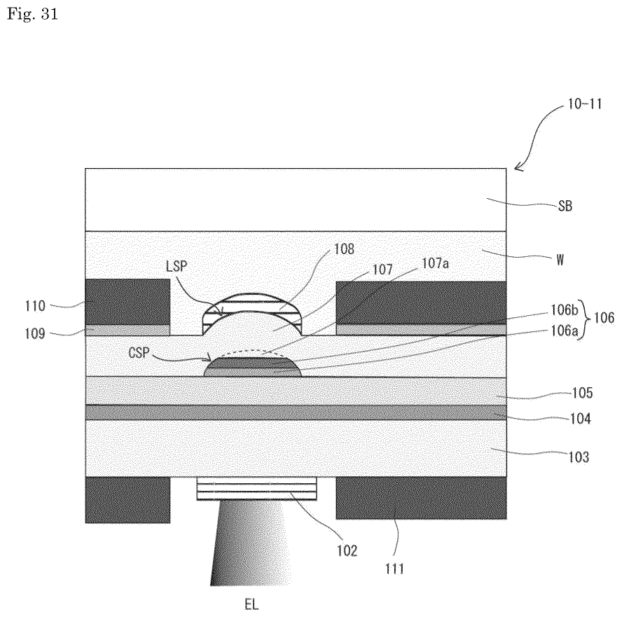

FIG. 31 is a cross-sectional view of a surface emitting laser 10-11 according to example 11 of the embodiment of the present technology. The surface emitting laser 10-11 employs the same configuration as that of the surface emitting laser 10-1 according to example 1 except that the surface emitting laser 10-11 includes the support base SB on the second reflection mirror 108 side instead of the substrate 101 (growth substrate), the first reflection mirror 102 is a dielectric multilayer film reflection mirror, and the cathode electrode 111 is provided on the back surface of the third semiconductor layer 103.

In the surface emitting laser 10-11, the support base SB is pasted on the surface on the second reflection mirror 108 side with the wax W interposed therebetween. In the surface emitting laser 10-11, the back surface (lower surface) of the dielectric multilayer film reflection mirror that is the first reflection mirror 102 is exposed, and is an emission side reflection mirror. That is, the surface emitting laser 10-11 is a back surface emission-type surface emitting laser.

In the surface emitting laser 10-11, the cathode electrode 111 of the circular shape (e.g., ring shape) is provided on the back surface of the third semiconductor layer 103 so as to surround the dielectric multilayer film reflection mirror that is the first reflection mirror 102.

Although the bump is not provided near the tunnel junction layer 106 of the first semiconductor layer 105 in the surface emitting laser 10-11, a bump formed by over etching may be provided similarly to the surface emitting laser 10-1 according to example 1.

### <<Operation of Surface Emitting Laser>>

The surface emitting laser 10-11 performs the same operation as that of the surface emitting laser 10-1 according to example 1 except that the first reflection mirror 102 emits the emission light EL.

### <<Manufacturing Method for Surface Emitting Laser>>

The manufacturing method for the surface emitting laser 10-11 will be briefly described. First, the third semiconductor layer 103, the active layer 104, the first semiconductor layer 105, the tunnel junction layer 106, the second semiconductor layer 107, the second reflection mirror 108, and the like are formed on the substrate 101 (growth substrate), then the support base SB is pasted on the second reflection mirror 108 side, and the substrate 101 (growth substrate) is removed. Next, the cathode electrode 111 is formed on the back surface (lower surface) of the third semiconductor layer 103. Next, the dielectric multilayer film reflection mirror that is the first reflection mirror 102 is formed inside of the cathode electrode 111.

### <<Effect of Surface Emitting Laser and Effect of Manufacturing Method for Surface Emitting Laser>>

According to the surface emitting laser 10-11, the dielectric multilayer film reflection mirror that can achieve high reflectance using a smaller number of pairs is used as the first reflection mirror 102, so that it is possible to provide the back surface emission-type surface emitting laser that easily achieves a high output. According to the manufacturing method for the surface emitting laser 10-11, it is possible to obtain the same effect as that of the manufacturing method for the surface emitting laser 10-1 according to example 1, and, since the electrode contact part ECP does not need to be formed, it is possible to simplify the manufacturing process.

### <12. Surface Emitting Laser According to Example 12 of Embodiment of Present Technology>

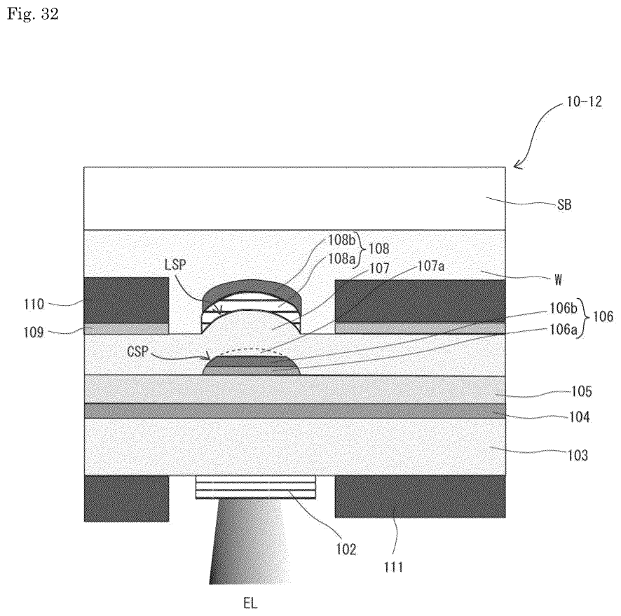

FIG. 32 is a cross-sectional view of the surface emitting laser 10-12 according to example 12 of the embodiment of the present technology. The surface emitting laser 10-12 employs the same configuration as that of the surface emitting laser 10-11 according to example 11 except that the second reflection mirror 108 is a hybrid mirror that includes a dielectric multilayer film reflection mirror 108a and a metal reflection mirror 108b as illustrated in FIG. 32.

In the surface emitting laser 10-12, the dielectric multilayer film reflection mirror 108a and the metal reflection mirror 108b that constitute the concave mirror as the second reflection mirror 108 are laminated in this order on the lens-shaped part LSP.

Although the bump is not provided near the tunnel junction layer 106 of the first semiconductor layer 105 in the surface emitting laser 10-12, a bump formed by over etching may be provided similarly to the surface emitting laser 10-1 according to example 1.

### <<Operation of Surface Emitting Laser>>

The surface emitting laser 10-12 performs the same operation as that of the surface emitting laser 10-1 according to example 1 except that the first reflection mirror 102 emits the emission light EL.

### <<Manufacturing Method for Surface Emitting Laser>>

The surface emitting laser 10-12 can be manufactured by the same manufacturing method as the manufacturing method for the surface emitting laser 10-11 according to example 11.

### <<Effect of Surface Emitting Laser and Effect of Manufacturing Method for Surface Emitting Laser>>

According to the surface emitting laser 10-12, the hybrid mirror that can achieve high reflectance using a smaller number of pairs and includes the dielectric multilayer film reflection mirror 108a and the metal reflection mirror 108b is used as the second reflection mirror 108, so that it is possible to provide the back surface emission-type surface emitting laser that can achieve high reflectance and improve heat dissipation. According to the manufacturing method for the surface emitting laser 10-12, it is possible to obtain the same effect as that of the manufacturing method for the surface emitting laser 10-11 according to example 11.

### <13. Surface Emitting Laser According to Example 13 of Embodiment of Present Technology>

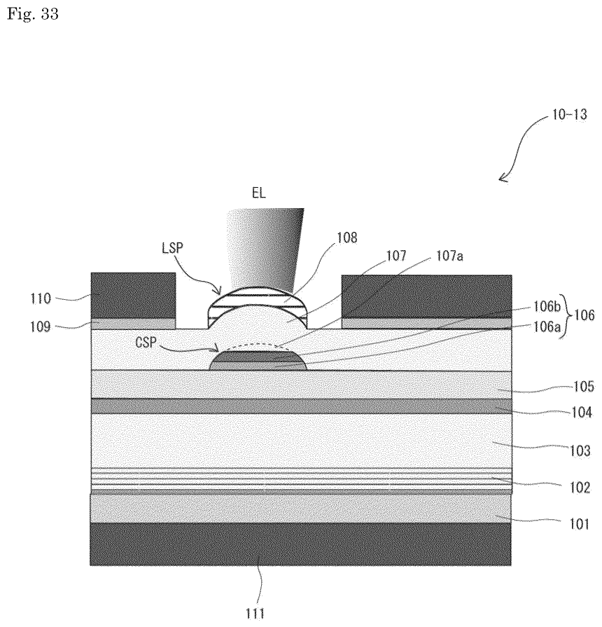

FIG. 33 is a cross-sectional view of the surface emitting laser 10-13 according to example 13 of the embodiment of the present technology. The surface emitting laser 10-13 employs substantially the same configuration as that of the surface emitting laser 10-1 according to example 1 except that the cathode electrode 111 is provided on the back surface of the substrate 101 as illustrated in FIG. 33.

In the surface emitting laser 10-13, the cathode electrode 111 is provided in a solid film state on the back surface of the substrate 101.

Although the bump is not provided near the tunnel junction layer 106 of the first semiconductor layer 105 in the surface emitting laser 10-13, a bump formed by over etching may be provided similarly to the surface emitting laser 10-1 according to example 1.

### <<Operation of Surface Emitting Laser>>

The surface emitting laser 10-13 performs the same operation as that of the surface emitting laser 10-1 according to example 1 except that a current path that crosses the first reflection mirror 102 and the substrate 101 is formed.

### <<Manufacturing Method for Surface Emitting Laser>>

The surface emitting laser 10-13 can be manufactured by the same manufacturing method as the manufacturing method for the surface emitting laser 10-1 according to example 1 except that the cathode electrode 111 is formed in the solid film state on the back surface of the substrate 101 without forming the electrode contact part ECP.

### <<Effect of Surface Emitting Laser and Manufacturing Method for Surface Emitting Laser>>

According to the surface emitting laser 10-13, it is possible to obtain the same effect as that of the surface emitting laser 10-1 according to example 1.

According to the manufacturing method for the surface emitting laser 10-13, it is possible to obtain the same effect as that of the manufacturing method for the surface emitting laser 10-1 according to example 1, and, since the electrode contact part ECP does not need to be formed, it is possible to simplify the manufacturing process.

### <14. Surface Emitting Laser According to Example 14 of Embodiment of Present Technology>

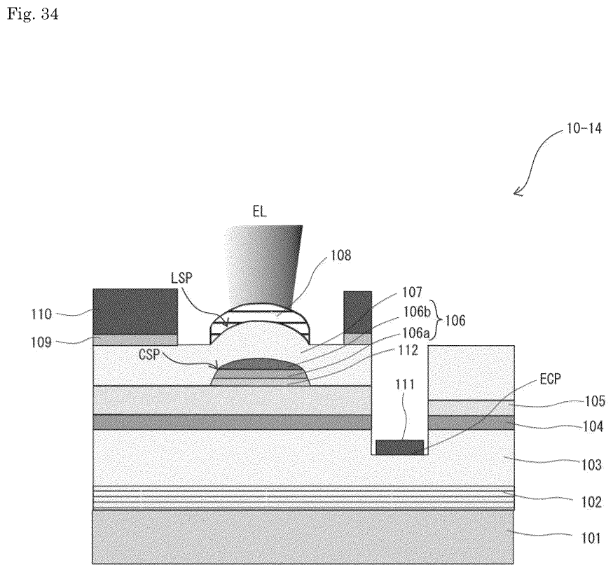

FIG. 34 is a cross-sectional view of a surface emitting laser 10-14 according to example 14 of the embodiment of the present technology. The surface emitting laser 10-14 employs the same configuration as that of the surface emitting laser 10-1 according to example 1 except that the cap layer 107a is not provided and the spacer layer 112 is provided as illustrated in FIG. 34.

In the surface emitting laser 10-14, the convex-shaped part CSP has a structure that the spacer layer 112 that constitutes at least the bottom part of the convex-shaped part CSP, the p-type semiconductor region 106a, and the n-type semiconductor region 106b are laminated in this order from the first semiconductor layer 105 side.

Although the bump is not provided near the tunnel junction layer 106 of the first semiconductor layer 105 in the surface emitting laser 10-14, a bump formed by over etching may be provided similarly to the surface emitting laser 10-1 according to example 1.

### <<Operation of Surface Emitting Laser>>

The surface emitting laser 10-14 performs the same operation as that of the surface emitting laser 10-1 according to example 1.

### <<Manufacturing Method for Surface Emitting Laser>>

The surface emitting laser 10-14 can be manufactured by substantially the same manufacturing method as the manufacturing method for the surface emitting laser 10-1 according to example 1.

### <<Effect of Surface Emitting Laser and Effect of Manufacturing Method for Surface Emitting Laser>>

According to the surface emitting laser 10-14, it is possible to obtain the same effect as that of the surface emitting laser 10-1 according to example 1.

According to the manufacturing method for the surface emitting laser 10-14, it is possible to obtain the same effect as that of the manufacturing method for the surface emitting laser 10-1 according to example 1.

### <15. Surface Emitting Laser According to Example 15 of Embodiment of Present Technology>

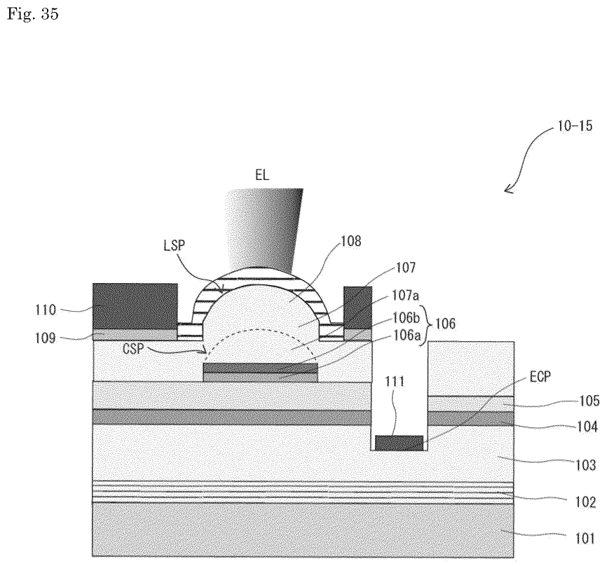

FIG. 35 is a cross-sectional view of a surface emitting laser 10-15 according to example 15 of the embodiment of the present technology. The surface emitting laser 10-15 employs substantially the same configuration as that of the surface emitting laser 10-1 according to example 1 except that the convex-shaped part CSP is provided on the face on the second reflection mirror 108 side of the tunnel junction layer 106 as illustrated in FIG. 35.

In the surface emitting laser 10-15, the convex-shaped part CSP is substantially formed by the cap layer 107a (e.g., n-InP layer).

Although the bump is not provided near the tunnel junction layer 106 of the first semiconductor layer 105 in the surface emitting laser 10-15, a bump formed by over etching may be provided similarly to the surface emitting laser 10-1 according to example 1.

### <<Operation of Surface Emitting Laser>>

The surface emitting laser 10-15 performs the same operation as that of the surface emitting laser 10-1 according to example 1.

### <<Manufacturing Method for Surface Emitting Laser>>

The surface emitting laser 10-15 can be manufactured by the substantially same manufacturing method as the manufacturing method for the surface emitting laser 10-1 according to example 1.

### <<Effect of Surface Emitting Laser and Effect of Manufacturing Method for Surface Emitting Laser>>

According to the surface emitting laser 10-15, it is possible to obtain the same effect as that of the surface emitting laser 10-1 according to example 1.

According to the manufacturing method for the surface emitting laser 10-15, it is possible to obtain the same effect as that of the manufacturing method for the surface emitting laser 10-1 according to example 1.

### <16. Surface Emitting Laser Array According to Example 16 of Embodiment of Present Technology>

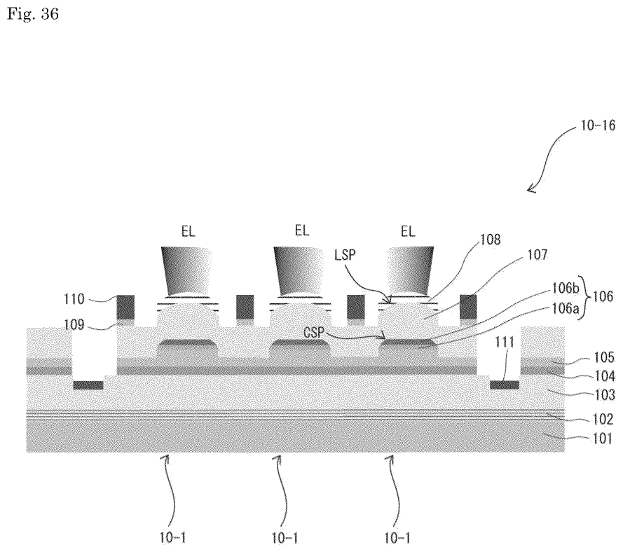

FIG. 36 is a cross-sectional view of a surface emitting laser array 10-16 according to example 16 of the embodiment of the present technology. In the surface emitting laser array 10-16, a plurality of the surface emitting lasers 10-1 are disposed in an array (e.g., a one-dimensional array or a two-dimensional array) as illustrated in FIG. 36.

### <<Operation of Surface Emitting Laser Array>>

The surface emitting lasers 10-1 are collectively or individually driven in the surface emitting laser array 10-16.

### <<Manufacturing Method for Surface Emitting Laser Array>>

As for the surface emitting laser array 10-16, for example, a semiconductor manufacturing method that uses a semiconductor manufacturing device simultaneously generates a plurality of the surface emitting laser arrays formed by arranging the plurality of surface emitting lasers 10-1 in an array on one wafer that is the base material of the substrate 101. Next, a series of the plurality of integrated surface emitting laser arrays are separated to obtain the plurality of chip-shaped surface emitting laser arrays (surface emitting laser array chips).

### <<Effect of Surface Emitting Laser and Effect of Manufacturing Method for Surface Emitting Laser>>

The surface emitting laser array 10-16 includes the plurality of surface emitting lasers 10-1 that cause little diffraction loss, so that it is possible to provide the surface emitting laser array that achieves a high output and high efficiency.

### <17. Modification Example of Present Technology>

The present technology is not limited to each example of the above embodiment, and can be variously modified. For example, the convex-shaped part CSP may be other shapes than the lens shape and the mesa shape.

For example, the contact layer 109 is not indispensable.

For example, a contact layer that is in contact with the cathode electrode 111 may be provided.

For example, the second reflection mirror 108 may include a semiconductor multilayer film reflection mirror. For example, at least one of the first and second reflection mirrors 102 and 108 may be a hybrid mirror formed by laminating the semiconductor multilayer film reflection mirror and the metal reflection mirror.

In the surface emitting laser and the surface emitting laser array according to each of the above examples, the conductive types (the p type and the n type) of the layers that constitute the semiconductor structure may be switched.

Part of the components of the surface emitting laser and the surface emitting laser array according to each of the examples may be combined without contradicting each other.

In each of the above examples, the material, the conductive type, the thickness, the width, the length, the shape, the size, the arrangement, and the like of each component that constitutes the surface emitting laser and the surface emitting laser array can be changed as appropriate as long as the surface emitting laser functions.

### <18. Example of Application to Electronic Device>

The technology according to the present disclosure (the present technology) can be applied to various products (electronic devices). For example, the technology according to the present disclosure may be implemented as a device equipped in any type of moving body such as an automobile, an electric vehicle, a hybrid electric vehicle, a motorcycle, a bicycle, a personal mobility device, an airplane, a drone, a ship, and a robot.

The surface emitting laser according to the present technology is also applicable as, for example, light sources of devices (e.g., a laser printer, a laser copier, a projector, a head mount display, and a head-up display) that form or display images with laser light.

### <19. Application of Surface Emitting Laser to Distance Measurement Device>

Hereinafter, an application example of the surface emitting laser according to each of the above examples will be described.

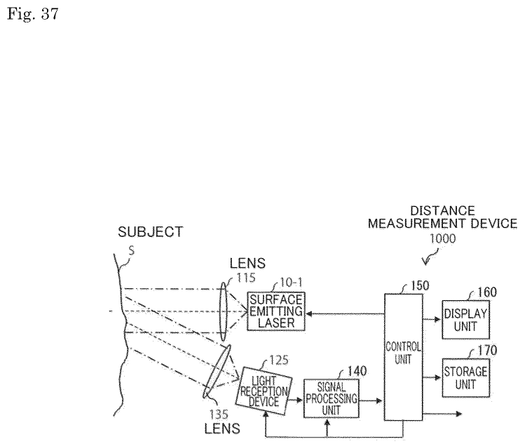

FIG. 37 illustrates an example of a schematic configuration of a distance measurement device 1000 that is an example of the electronic device and includes the surface emitting laser 10-1. The distance measurement device 1000 measures a distance to a subject S by the Time Of Flight (TOF) method. The distance measurement device 1000 includes the surface emitting laser 10-1 as a light source. The distance measurement device 1000 includes, for example, the surface emitting laser 10-1, a light reception device 125, lenses 115 and 135, a signal processing unit 140, a control unit 150, a display unit 160, and a storage unit 170.

The light reception device 125 detects light reflected by the subject S. The lens 115 is a lens for parallelizing the light emitted from the surface emitting laser 10-1, and is a collimator lens. The lens 135 is a lens that condenses light reflected by the subject S and guides the light to the light reception device 125, and is a condenser lens.

The signal processing unit 140 is a circuit that generates a signal corresponding to a difference between a signal input from the light reception device 125 and a reference signal input from the control unit 150. The control unit 150 includes, for example, a Time to Digital Converter (TDC). The reference signal may be a signal input from the control unit 150, or may be an output signal of a detection unit that directly detects an output of the surface emitting laser 10-1. The control unit 150 is, for example, a processor that controls the surface emitting laser 10-1, the light reception device 125, the signal processing unit 140, the display unit 160, and the storage unit 170. The control unit 150 is a circuit that measures the distance to the subject S on the basis of the signal generated by the signal processing unit 140. The control unit 150 generates a video signal for displaying information on the distance to the subject S, and outputs the video signal to the display unit 160. The display unit 160 displays the information on the distance to the subject S on the basis of the video signal input from the control unit 150. The control unit 150 stores the information on the distance to the subject S in the storage unit 170.

In this application example, instead of the surface emitting laser 10-1, one of the above surface emitting lasers 10-2 to 10-15 and the surface emitting laser array 10-16 can be also applied to the distance measurement device 1000.

### <20. Example Where Distance Measurement Device is Mounted on Moving Body>

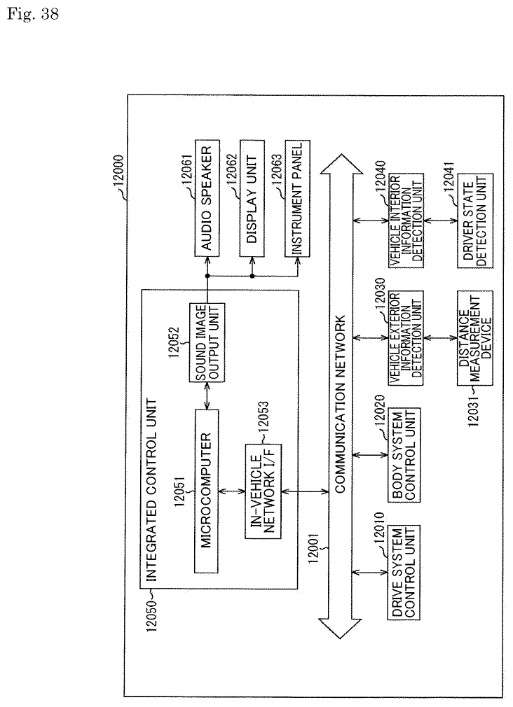

FIG. 38 is a block diagram illustrating a schematic configuration example of a vehicle control system that is an example of a moving body control system to which the technique according to the present disclosure can be applied.

A vehicle control system 12000 includes a plurality of electronic control units connected thereto via a communication network 12001. In the example illustrated in FIG. 38, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, a sound image output unit 12052, and an in-vehicle network interface (I/F) 12053 are illustrated.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle on which the vehicle control system 12000 is mounted. For example, the vehicle exterior information detection unit 12030 is connected with a distance measurement device 12031. The distance measurement device 12031 includes the above-described distance measurement device 1000. The vehicle exterior information detection unit 12030 causes the distance measurement device 12031 to measure a distance to an object (subject S) outside of the vehicle, and acquires distance data obtained by the measurement. The vehicle exterior information detection unit 12030 may perform object detection processing for people, vehicles, obstacles, signs, and the like on the basis of the acquired distance data.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of information on the inside and the outside of the vehicle acquired by the vehicle exterior information detection unit 12030 or the vehicle interior information detection unit 12040, and output a control command to the drive system control unit 12010. For example, the microcomputer 12051 can perform cooperative control for the purpose of implementing functions of an Advanced Driver Assistance System (ADAS) including vehicle collision avoidance, impact mitigation, following traveling based on an inter-vehicle distance, vehicle speed maintenance driving, vehicle collision warning, vehicle lane deviation warning, and the like.

In addition, the microcomputer 12051 can perform cooperative control for the purpose of automated driving or the like in which autonomous travel is performed without depending on operations of the driver, by controlling the driving force generator, the steering mechanism, the braking device, or the like on the basis of information on the surroundings of the vehicle acquired by the vehicle exterior information detection unit 12030 or the vehicle interior information detection unit 12040.

In addition, the microcomputer 12051 can output a control command to the body system control unit 12020 based on the information on the outside of the vehicle acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The sound image output unit 12052 transmits an output signal of at least one of sound and an image to an output device capable of visually or audibly notifying a passenger or the outside of the vehicle of information. In the example in FIG. 38, an audio speaker 12061, a display unit 12062, and an instrument panel 12063 are illustrated as examples of the output device. The display unit 12062 may include at least one of an on-board display and a head-up display, for example.

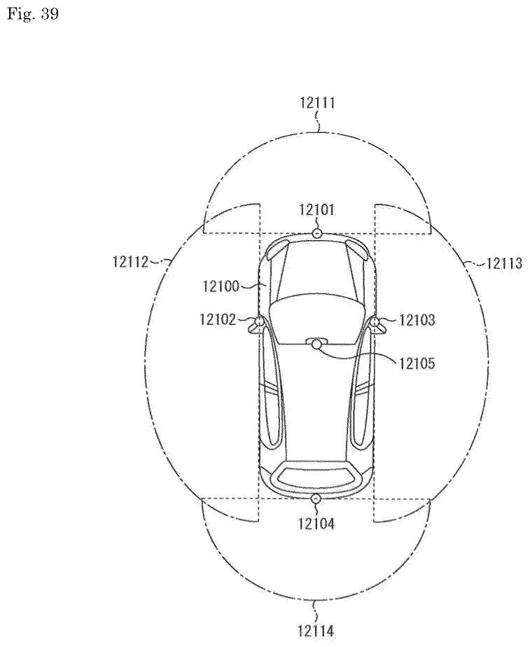

FIG. 39 is a diagram illustrating an example of an installation position of the distance measurement device 12031.

In FIG. 39, a vehicle 12100 includes distance measurement devices 12101, 12102, 12103, 12104, and 12105 as the distance measurement device 12031.

The distance measurement devices 12101, 12102, 12103, 12104, and 12105 are provided at, for example, positions of a front nose, side mirrors, a rear bumper, a back door, an upper part of a vehicle internal front windshield, and the like of the vehicle 12100. The distance measurement device 12101 provided on the front nose and the distance measurement device 12105 provided at an upper part of the front windshield inside of the vehicle compartment mainly acquire data of a region in front of the vehicle 12100. The distance measurement devices 12102 and 12103 included in the side mirrors mainly acquire data of regions on the sides of the vehicle 12100. The distance measurement device 12104 included in the rear bumper or the back door mainly acquires data of a region behind the vehicle 12100. The data of the front region acquired by the distance measurement devices 12101 and 12105 are mainly used for detection of preceding vehicles, pedestrians, obstacles, traffic lights, traffic signs, and the like.

Note that FIG. 39 illustrates an example of detection ranges of the distance measurement devices 12101 to 12104. A detection range 12111 indicates a detection range of the distance measurement device 12101 provided at the front nose, detection ranges 12112 and 12113 respectively indicate detection ranges of the distance measurement devices 12102 and 12103 provided at the side mirrors, and a detection range 12114 indicates a detection range of the distance measurement device 12104 provided at the rear bumper or the back door.

By, for example, obtaining a distance to each three-dimensional object in the detection ranges 12111 to 12114 and temporal change in the distance (a relative speed with respect to the vehicle 12100) on the basis of distance data obtained from the distance measurement devices 12101 to 12104, the microcomputer 12051 can extract as a preceding vehicle, particularly, a closest three-dimensional object that is on a path of the vehicle 12100 and is traveling at a predetermined speed (e.g., 0 km/h or higher) in substantially the same direction as that of the vehicle 12100. Furthermore, the microcomputer 12051 can also set an inter-vehicle distance that needs to be secured in advance in front of the preceding vehicle, and perform automatic brake control (including tracking stop control, too) and automatic acceleration control (including tracking start control, too). Thus, it is possible to perform cooperative control for the purpose of, for example, automated driving in which the vehicle travels in an automated manner without requiring the driver to perform operations.

For example, the microcomputer 12051 can classify and extract three-dimensional data regarding three-dimensional objects as two-wheeled vehicles, normal vehicles, large vehicles, pedestrians, and other three-dimensional objects such as electric poles on the basis of the distance data obtained from the distance measurement devices 12101 to 12104 and can use the three-dimensional data for automated avoidance of obstacles. For example, the microcomputer 12051 identifies obstacles in the vicinity of the vehicle 12100 into obstacles that can be visually recognized by the driver of the vehicle 12100 and obstacles that are difficult to be visually recognized by the driver. Then, the microcomputer 12051 can determine a risk of collision indicating the degree of risk of collision with each obstacle and can perform driving assistance for collision avoidance by outputting a warning to the driver through the audio speaker 12061 or the display unit 12062 and performing forced deceleration or avoidance steering through the drive system control unit 12010 when the risk of collision has a value equal to or greater than a set value and there is a possibility of collision.

An example of the moving body control system to which the technology according to the present disclosure can be applied has been described above. The technology according to the present disclosure can be applied to the distance measurement device 12031 among the configurations described above.

In addition, the present technology can also have the following configurations.

(1) A surface emitting laser includes: first and second reflection mirrors; and a semiconductor structure that is disposed between the first and second reflection mirrors, and the semiconductor structure internally includes a convex-shaped part to which a current constriction region is set, and that protrudes toward a side of the second reflection mirror, and includes a lens-shaped part that meets the convex-shaped part on a top layer on the side of the second reflection mirror.

(2) In the surface emitting laser described in (1), the lens-shaped part protrudes toward the side of the second reflection mirror, and the second reflection mirror is a concave mirror that is provided along the lens-shaped part.

(3) In the surface emitting laser described in (1) or (2), the convex-shaped part has a lens shape.

(4) In the surface emitting laser described in (1) or (2), the convex-shaped part has a mesa shape.

(5) In the surface emitting laser described in any one of (1) to (4), the convex-shaped part includes a tunnel junction layer.

(6) In the surface emitting laser described in (5), the convex-shaped part further includes at least one layer that is laminated on the tunnel junction layer.

(7) In the surface emitting laser described in (6), the at least one layer includes a cap layer that constitutes at least a top part of the convex-shaped part.

(8) In the surface emitting laser described in (7), the cap layer is made of the same material as a material of the top layer.

(9) In the surface emitting laser described in any one of (6) to (8), the at least one layer includes a spacer layer that constitutes at least a bottom part of the convex-shaped part.

(10) In the surface emitting laser described in (5), the convex-shaped part includes only the tunnel junction layer.

(11) In the surface emitting laser described in any one of (1) to (4), the semiconductor structure includes a tunnel junction layer, and the convex-shaped part is provided on a face of the tunnel junction layer on the side of second reflection mirror.

(12) In the surface emitting laser described in any one of (1) to (11), the semiconductor structure includes an active layer that is disposed on a side of the first reflection mirror of the convex-shaped part, a first semiconductor layer that is disposed between the convex-shaped part and the active layer, and a second semiconductor layer that buries surroundings of the convex-shaped part and includes the lens-shaped part.

(13) In the surface emitting laser described in (12), a thickness of a portion of the first semiconductor layer that does not meet the convex-shaped part is thinner than a thickness of a portion that meets the convex-shaped part.

(14) In the surface emitting laser described in any one of (5) to (13), the tunnel junction layer includes a p-type semiconductor region and an n-type semiconductor region that are mutually laminated, and at least one of the p-type semiconductor region and the n-type semiconductor region is made of InP.

(15) In the surface emitting laser described in any one of (5) to (14), the tunnel junction layer includes a p-type semiconductor region and an n-type semiconductor region that are mutually laminated, and at least one of the p-type semiconductor region and the n-type semiconductor region is made of AlGaInAs.

(16) In the surface emitting laser described in any one of (1) to (15), the first reflection mirror is a semiconductor multilayer film reflection mirror or a dielectric multilayer film reflection mirror.

(17) In the surface emitting laser described in any one of (1) to (16), one of the first and second reflection mirrors has a laminated structure in which a multilayer film reflection mirror and a metal reflection mirror are laminated.

(18) A surface emitting laser array that is formed by disposing in an array a plurality of the surface emitting lasers described in any one of (1) to (17).

(19) A manufacturing method for a surface emitting laser includes:
laminating a plurality of semiconductor layers on a substrate, and generating a laminated body;
forming a resist of a lens shape on the laminated body;
etching the laminated body using the resist as a mask, and forming a convex-shaped part of a lens shape;
laminating a buried layer on the laminated body in which the convex-shaped part has been formed, and forming in the buried layer a lens-shaped part that meets the convex-shaped part; and
forming a reflection mirror on the lens-shaped part.

(20) A manufacturing method for a surface emitting layer including: laminating a plurality of semiconductor layers on a substrate, and generating a laminated body;
forming a resist of a convex shape on the laminated body;
etching the laminated body using the resist as a mask, and forming a first convex-shaped part;
laminating a buried layer on the laminated body in which the first convex-shaped part has been formed, and forming in the buried layer a second convex-shaped part that meets the first convex-shaped part;
etching the second convex-shaped part, and forming a lens-shaped part; and
forming a reflection mirror on the lens-shaped part.

### REFERENCE SIGNS LIST

10-1 to 10-15 Surface emitting laser
101 Substrate
102 First reflection mirror
104 Active layer
105 First semiconductor layer
106 Tunnel junction layer
107 Second semiconductor layer
107a Cap layer
108 Second reflection mirror
112 Spacer layer
SS Semiconductor structure
CSP Convex-shaped part
LSP Lens-shaped part

1. A surface emitting laser comprising:
first and second reflection mirrors; and
a semiconductor structure that is disposed between the first and second reflection mirrors,
wherein the semiconductor structure internally includes a convex-shaped part to which a current constriction region is set, and that protrudes toward a side of the second reflection mirror, and includes a lens-shaped part that meets the convex-shaped part on a top layer on the side of the second reflection mirror.

2. The surface emitting laser according to claim 1, wherein
the lens-shaped part protrudes toward the side of the second reflection mirror, and
the second reflection mirror is a concave mirror that is provided along the lens-shaped part.

3. The surface emitting laser according to claim 1, wherein the convex-shaped part has a lens shape.

4. The surface emitting laser according to claim 1, wherein the convex-shaped part has a mesa shape.

5. The surface emitting laser according to claim 1, wherein the convex-shaped part includes a tunnel junction layer.

6. The surface emitting laser according to claim 5, wherein the convex-shaped part further includes at least one layer that is laminated on the tunnel junction layer.

7. The surface emitting laser according to claim 6, wherein the at least one layer includes a cap layer that constitutes at least a top part of the convex-shaped part.

8. The surface emitting laser according to claim 7, wherein the cap layer is made of the same material as a material of the top layer.

9. The surface emitting laser according to claim 6, wherein the at least one layer includes a spacer layer that constitutes at least a bottom part of the convex-shaped part.

10. The surface emitting laser according to claim 5, wherein the convex-shaped part includes only the tunnel junction layer.

11. The surface emitting laser according to claim 1, wherein
the semiconductor structure includes a tunnel junction layer, and
the convex-shaped part is provided on a face of the tunnel junction layer on the side of second reflection mirror.

12. The surface emitting laser according to claim 1, wherein the semiconductor structure includes
an active layer that is disposed on a side of the first reflection mirror of the convex-shaped part,
a first semiconductor layer that is disposed between the convex-shaped part and the active layer, and
a second semiconductor layer that buries surroundings of the convex-shaped part and includes the lens-shaped part.

13. The surface emitting laser according to claim 12, wherein a thickness of a portion of the first semiconductor layer that does not meet the convex-shaped part is thinner than a thickness of a portion that meets the convex-shaped part.

14. The surface emitting laser according to claim 5, wherein
the tunnel junction layer includes a p-type semiconductor region and an n-type semiconductor region that are mutually laminated, and
at least one of the p-type semiconductor region and the n-type semiconductor region is made of InP.

15. The surface emitting laser according to claim 5, wherein
the tunnel junction layer includes a p-type semiconductor region and an n-type semiconductor region that are mutually laminated, and
at least one of the p-type semiconductor region and the n-type semiconductor region is made of AlGaInAs.

16. The surface emitting laser according to claim 1, wherein the first reflection mirror is a semiconductor multilayer film reflection mirror or a dielectric multilayer film reflection mirror.

17. The surface emitting laser according to claim 1, wherein one of the first and second reflection mirrors has a laminated structure in which a multilayer film reflection mirror and a metal reflection mirror are laminated.

18. A surface emitting laser array that is formed by disposing in an array a plurality of the surface emitting lasers according to claim 1.

19. A manufacturing method for a surface emitting laser comprising:
laminating a plurality of semiconductor layers on a substrate, and generating a laminated body;
forming a resist of a lens shape on the laminated body;
etching the laminated body using the resist as a mask, and forming a convex-shaped part of a lens shape;
laminating a buried layer on the laminated body in which the convex shaped part has been formed, and forming in the buried layer a lens-shaped part that meets the convex shaped part; and
forming a reflection mirror on the lens-shaped part.

20. A manufacturing method for a surface emitting laser comprising:
laminating a plurality of semiconductor layers on a substrate, and generating a laminated body;
forming a resist of a convex shape on the laminated body;
etching the laminated body using the resist as a mask, and forming a first convex-shaped part;
laminating a buried layer on the laminated body in which the first convex shaped part has been formed, and forming in the buried layer a second convex shaped part that meets the first convex shaped part;
etching the second convex shaped part, and forming a lens-shaped part; and
forming a reflection mirror on the lens-shaped part.
